(19) United States
(12) Patent Application Publication
(10) Pub. No.: US 2025/0216436 A1
(43) Pub. Date: Jul. 3, 2025

(54) DEVICE AND METHOD FOR DETECTING DISCONNECTION FAULT OF OVERHEAD POWER LINE

(71) Applicant: Hyun Chang LEE, Gyeonggi-do (KR)

(72) Inventor: Hyun Chang LEE, Gyeonggi-do (KR)

(21) Appl. No.: 19/082,098

(22) Filed: Mar. 17, 2025

Related U.S. Application Data
(63) Continuation of application No. PCT/KR2023/014102, filed on Sep. 1, 2023.

(30) Foreign Application Priority Data
Sep. 16, 2022 (KR) 10-2022-0116720
Sep. 18, 2023 (KR) 10-2023-0124345

(51) Int. Cl. G01R 31/08; G01R 15/18; G01R 31/54; G01R 33/00

(52) U.S. Cl. CPC G01R 31/085; G01R 31/088; G01R 31/54; G01R 33/0029; G01R 15/183

(57) ABSTRACT

The present application relates to a device and method for surveying a power line-buried path, wherein the device includes a transmitter which selects a balanced/unbalanced voltage to output input and rectified output power as a current pulse in the form of an unmodulated pulse or a frequency-modulated signal when a current pulse signal is transmitted to a conductor (power line) of a public distribution network, and a receiver in which a plurality of magnetic field sensors inductively couple the pulse or the frequency-modulated signal within a near magnetic field distance to obtain a difference value in each direction to obtain a depth.

### CROSS-REFERENCE TO RELATED APPLICATION

This application is a US Bypass Continuation Application of International Application No. PCT/KR2023/014102, filed on Sep. 18, 2023, which claims priority to and the benefit of Korean Patent Application No. 10-2022-0116720, filed on Sep. 16, 2022, and Korean Patent Application No. 10-2023-0124345, filed on Sep. 18, 2023, the disclosure of which is incorporated herein by reference in its entirety.

### BACKGROUND

### Technical Field

The present application describes a device and method for transmitting and receiving a current pulse signal to and from a conductor (power line) within a public distribution network. The goal is to address the issue where an overhead power line can become disconnected and fall to the ground without triggering a fault current due to its high impedance. Consequently, backup protection systems, such as substation circuit breakers, reclosers, and load switches, may not function properly. The proposed method involves transmitting a current pulse signal through a transformer on the load side and receiving the signal on the opposite power source side. This allows for monitoring disconnections, and if a disconnection is detected, the system can coordinate with backup protection devices to cut off the power as needed.

### Background Art

In public power networks, conductors (wires or power lines) are essential for transmitting electricity from the power plant to customers. These power lines operate at high voltages and require proper insulation. Specifically, when polyphase systems are used, each phase and the ground must be insulated appropriately.

The public power network consists of either an overhead installation where power lines are mounted on poles (towers) above ground or an underground installation where power lines are laid underground after excavation

In overhead installations, the public power network uses supports (insulators) with appropriate insulation grades for each voltage on the poles (or towers), which are designed to hold the uninsulated wires. In this setup, the insulation between the phases of the power line is maintained by the distance between the supports, while the insulation with the ground is ensured by the height of the poles (or towers). The medium present in each insulation gap is air.

In overhead installations, the public power networks are exposed to natural elements and significantly impacted by weather conditions. During strong winds, the supports and wires attached to the poles can undergo mechanical wear due to friction and vibration, which increases the risk of power line failures. When a power line fails, it may become detached from its support and fall to the ground. This can create an arc that ignites nearby flammable materials, potentially leading to large-scale forest fires.

Overhead conductor of a public power network include bare conductors using an aluminum wire as a core, and covered conductors in which an outer surface of a bare conductor is wrapped with polyethylene (PE) to prevent corrosion.

As transmission lines in public power networks, bare conductors are generally used, but as distribution lines, covered conductors are used to prevent a fault due to contact with trees because of a low ground clearance.

In this application, we will focus on distribution lines that operate at voltages of 35 kV or lower, which is considered lower than transmission voltage. These distribution lines usually experience low ground fault currents, calculated using the formula (If=V/R).

Furthermore, when covered conductors are used, the ground fault current is nearly nonexistent, even if the conductor comes into contact with the ground. However, it's important to emphasize that these principles do not apply to transmission lines, which often operate under different conditions.

In particular, when a distribution network uses a covered conductor, the fault current will be much lower than the pick-up current, even if the conductor is disconnected and makes contact with an asphalt-paved surface or dry ground during the dry season. Similarly, if a disconnected wire is suspended in the air, creating a loose connection without making solid contact with the ground, the fault current will also be minimal or nonexistent.

In South Korea, a 22.9 kV class distribution line with a solidly grounded Y system will trigger a substation circuit breaker if the current flowing through any of the phase lines exceeds 400 A or if the ground current exceeds 70 A. When this occurs, the circuit breaker trips, cutting off the power supply to the faulted distribution line and reducing its voltage to zero. This action helps prevent further faults or accidents.

Even if a ground fault occurs in the overhead line, the ground fault current may be significantly lower than 70 A. As a result, the ground fault circuit may not be sufficient to activate the substation circuit breaker and disconnect the power supply. If the breaker fails to detect this ground fault, it will not trip, leaving the faulty conductor energized and posing a danger, as high voltage remains within reach.

A charged conductor can become detached from its support and easily be moved by strong winds, potentially causing arc sparks that could ignite nearby combustible materials. If the power supply is interrupted in time, it may be possible to prevent a fire. However, because a disconnection fault often goes unnoticed, a charged wire can produce arc sparks for an extended period, which can lead to a larger fire.

In conventional technologies, detecting and identifying a disconnected and fallen distribution line that runs from a power source (substation) toward a load is achieved by measuring the voltage and current of the zero-phase (negative-phase) or arc current. However, even if a disconnected wire makes contact with the ground, a fault may not be detected because a ground current does not flow due to high impedance.

Additionally, most areas affected by forest fires are situated in light-load zones that are beyond the load center. As a result, even if a faulted conductor disconnects a supply circuit, the change in load current is minimal.

Furthermore, if a ground-faulted conductor comes into contact with the ground and generates an arc current, it is highly unlikely that the backup protection device will detect the short-term arc fault current in lines located beyond the heavy load center.

Moreover, identifying a short circuit fault and removing the faulty wire takes a considerable amount of time.

Recent investigations revealed that the forest fires in Goseong, South Korea, in 2018 and 2019, as well as the fire in Gangneung, Gangwon Province, in April 2023, were primarily caused by ground faults resulting from the disconnection of power distribution lines.

In the United States, a major forest fire incident caused by a power line disconnection led to the implementation of a Public Safety Power Shut-off (PSPS) program. Now, whenever strong winds of 30 km/h (approximately 18.6 mph) or more are forecasted, power companies proactively shut off the power lines, including distribution lines. This measure aims to fundamentally prevent forest fires that may be triggered by power line disconnections.

The introduction and management of the Public Safety Power Shutoff (PSPS) program recognize that disconnections in power lines during strong winds are a significant contributor to forest fires. The program reflects a commitment to address this issue, as the damage caused by forest fires is far greater than the impact of power outages that occur before the onset of strong winds.

Other countries do not currently have such systems in place. However, if delays in technological advancements make it impossible to reliably prevent forest fire disasters caused by power line faults, these countries will eventually have to implement similar programs.

Conventional technologies for detecting power line disconnection faults include O'Brien's U.S. Pat. No. 9,413,156B2 (citation 1), which describes a method for detecting a signature—an electrical characteristic that includes load current, voltage, phase, and time—at the power source of a distribution line. Additionally, Jung's Korean Published Patents KR20150024017A (citation 2) and KR101350618B1 (citation 3) detail a process where load current deviation or current voltage is measured for each section of the distribution line. From these measurements, normal and reverse phase component changes, as well as arc components, are identified to detect wire disconnection faults.

However, as noted, if a wire disconnection fault occurs and no fault current flows, it becomes impossible to detect the fault. In Korean Patent KR20180029696A (citation 4), a disconnection fault is detected using a support tension sensor. There is a need to consider costs for installing sensors in every electric post and constituting a network for performing remote monitoring.

In Korean Registered Patent KR102061929B1 (citation 5), when a pulse signal with a frequency different from the power frequency is applied to the high-voltage neutral point of a Y-connected transformer, a superimposed signal is transmitted to the neutral point of the opposite transformer through the power line. This process allows for checking whether there is a disconnection.

Lee's Korean Registered Patent KR100816101B1 (citation 6) describes a method for superimposing an asymmetric pulse signal onto a neutral point of a transformer and detecting the signal at a leakage current point.

Underground distribution installations differ from overhead line installations in that they utilize insulated cables to transmit power. These cables are placed inside conduits, eliminating the need for external supports.

Because the insulated cables are protected from exposure, the risk of ground failures is relatively low. However, ground failures can still occur due to ground deformation or excavation work triggered by floods or earthquakes, which necessitates monitoring.

As shown in FIG. 1, a public distribution network 50 is divided into a medium voltage section 30 and a low voltage section 40, and a transformer 20 is placed therebetween. In general, when the power from a power source 31 in the medium voltage section reaches the transformer 20 through a medium voltage line 32, a voltage is converted into a voltage of a low voltage section 40 through magnetic flux coupling, and thus power is supplied to a low voltage load 41 (customer) through a low voltage line 42 in a hierarchical structure. Here, the voltage of the low voltage section 40 is usually a voltage of 1,000 V or less, and the transformer 20 is designed exclusively for AC such that medium and low voltage sections may be mutually flux-coupled.

According to FIG. 2, a separate exploration power source (Tx) is connected to either the sheath line (32-n) or neutral line (not shown) of an unenergized power line to send an AC signal with a frequency greater than 1 kHz, which is distinct from the power frequency (50 or 60 Hz). to explore the buried path of power line using the receiver (Rx).

However, signal loss occurs when a plurality of multi-grounding sheath lines is used as transmission lines, and in addition, the use of high-frequency signals with a frequency that is much higher than a power frequency makes it difficult to accurately distinguish target lines due to inductive and electrostatic coupling with nearby lines.

FIG. 3 describes the principle of citation 5. A three-phase power line is connected through Y-connected transformers at both ends, and when a neutral point, a ground connection line 79, and a transmitter 73 are inductively coupled (83) at a transformer 71 to inject a pulse signal (74), a superimposed signal flows to the ground through a neutral point of an opposite side transformer 72 through a three-phase power line circuit. In FIG. 3A, the input signal is divided into three phase power lines 75, 76, and 77 to flow, and thus all signals are detected at a neutral point grounding line 74 of the opposite side transformer. However, in FIG. 3B, it is described that a current 85 of one phase is not transmitted, and therefore, only currents 86 and 87 of two phases excluding the current 85 are detected at a neutral point grounding line 83 of an opposite side transformer.

That is, a zero-phase current flowing in a three-phase power line connecting both ends of a high voltage line is transmitted through a neutral point of a transformer and received as a zero-phase current by the opposite side transformer. When a disconnection fault occurs, a change in current is detected to identify the disconnection fault.

FIG. 4 describes that, when a signal is input to a transformer neutral point and a ground line, the signal is divided and transmitted to a primary high voltage line as well as a secondary low voltage line. In citation 4 of FIG. 4A, there are provided a primary high voltage winding 14 and a secondary low voltage winding 16 of a transformer. In citation 5 of FIG. 4B, it can be seen that a signal input to a transformer neutral line is returned to a multi-ground of a neutral line of a low voltage line. That is, in citation 4, a 3-wire transmission method is actually used physically, but in a 4-wire transmission method as shown in FIG. 4B in which a neutral line is included in a transmission line, since a neutral point of a transformer is multi-grounded in a plurality of places, a zero-phase current cannot be transmitted to another transformer.

In summary, citation 4 is a technology that is possible in a configuration in which, when a high voltage line is a three-phase line, three wires are used, but transformers at both ends have a neutral point. When distribution lines are two wires (phase line+neutral line) in a single phase or four wires (three phase lines+neutral line) in three phases, since an actual neutral line is physically connected to an opposite side transformer and grounded in the middle, a superimposed signal will return to a signal transmission transformer through a neutral line ground and will not be transmitted to the opposite side transformer.

Accordingly, even in a transformer connection environment that, irrespective of whether a fault current occurs, is not affected by a load current flowing in a power line and does not use a neutral line, a high voltage line disconnection fault should be detected in both underground and overhead distribution types irrespective of low voltage line multi-grounding.

In order to solve such problems, in Registered Patent No. KR10-2181831, a technology was developed to survey a medium voltage line 32 by being connected to a single-phase power source of a low voltage line 42 as shown in FIG. 3.

### SUMMARY

### Technical Problem

Transformers in a public distribution network are tightly coupled, and as shown in FIG. 3, when a unipolar high current pulse flows, a high voltage may be generated by an inertial action, which develops into ferroresonance in the worst case scenario, and thus, due to concerns that a power system may collapse triggered by a cascading failure, this has not been implemented often so far.
1. In the conventional technology of FIG. 3, a transmitter operates using a single-phase power source, and thus, in the case of a polyphase, the phase connection should be manually changed each time to survey a multi-phase power source. Therefore, if a public distribution network contains a polyphase power source, the phase connection of a transmitter should be altered by a program.
2. Recently, the rapidly increasing distributed energy resources have been operating as a leading power factor, and the transmitters at locations far from the transformers induce current from the distributed energy resources rather than the public distribution networks, resulting in losses that cannot be transmitted to the public distribution networks. In order to transmit the output to the public distribution network as much as possible, the transmitters need to be moved closer to the transformers. However, no proper countermeasure has been established for the adverse effects of a high current pulse near the transformers.
1) Even when a high current is generated for a short time near a secondary winding of a transformer, it is necessary to prevent the occurrence of transient voltages that cause system instability.
2) When a unipolar nonlinear current is excited in a transformer, it is necessary to prevent a residual magnetic flux from accumulating in a ferromagnetic part.
3) In order to prevent a resonance phenomenon between a transmitter and a transformer, electrical circuits should be isolated during an idle time (T−t), even if they are physically connected.
4) It should be possible to transmit nonlinear current signals to a public distribution network without violating the harmonic wave output limits set by regulation (IEC 61000 3-2).
3. The power frequency used by the public distribution network varies depending on the load demanded. Consequently, the inductively coupled receiver 11 cannot use the synchronous signal.
1) The receiver should be able to receive a transmitted signal without depending on a power frequency.
2) A magnetic field signal generated by a current pulse should be detectable even when it is diminished through destructive interference rather than constructive interference in surrounding noise.
3) The depth information for the buried power line should be provided.

### Technical Solution

Provided is a method of surveying a power line by changing a pulse/frequency mode using a balanced/unbalanced three-phase voltage source and transmitting a current pulse signal to a public distribution network.

Provided is a device for surveying a power line by changing a pulse/frequency mode using a balanced/unbalanced three-phase voltage source and transmitting a current pulse signal to a public distribution network.

There is provided a device for surveying a power line by changing a pulse/frequency mode using a balanced/unbalanced three-phase voltage source and transmitting a current pulse signal to a public distribution network, and the device includes a transmitter and a receiver, wherein the transmitter includes a connection unit configured to receive a single-phase AC voltage at a point of connection (POC) which is a point of the public distribution network, a converter unit configured to convert an input AC voltage into a DC voltage (V+), an inverter unit configured to switch a DC voltage (V+) of a converter at a set phase angle time and transmit a current pulse signal to a power source of the public distribution network through a pure resistive load (L_{R}), and a DC_link unit provided between the inverter unit and the converter unit and configured to suppress a transient voltage.

The DC_link unit may include an accumulator.

A first closed circuit that begins at the connection point (POC) of the connection unit, then extends to the converter and the accumulator and one terminal of the transformer's secondary winding.

The inverter unit may include a load resistor and a switch connected in series, and a second closed circuit includes a load resistor of the inverter in parallel connection with one end of the accumulation means of the first closed circuit, and a switch connected in series with the load resistor connects to the remaining end of the accumulation means of the first closed circuit parallelly.

Charging the maximum capacity of the above-mentioned accumulating means to its maximum voltage; the second closed circuit remains in the OFF state until the gate control signal for the switch is received. This setup electrically isolates the secondary winding of the transformer from the transmitter, preventing ferroresonance.

The transmitter may receive unbalanced three-phase input power to perform a full-wave rectification, select one phase of three phases through a program, and output a dipolar current pulse signal to the one phase and a neutral line at a half-cycle interval.

The device for surveying a power line may be controlled so that when a switch (SW) is turned on (P1), the accumulator supplies a charged current to a load for a certain period. After this time, the cathode voltage of a diode (D) is lowered, altered, and forward biased to electrically connect the transformer and the transmitter.

The receiver may include a magnetic field receiving unit inductively coupled to a medium voltage line within a near magnetic field distance to obtain an induced current through a coil wound on a ferromagnetic part, a signal detection unit including a signal detector configured to capture a collected magnetic field signal, a signal processor configured to remove a power frequency and a harmonic signal including a load current contained in the magnetic field signal, a detection adjuster configured to adjust a gain and a TH value for specific signal detection, and a microcontroller unit (MCU) configured to transmit collected signal detection-related data, and a waveform analysis unit configured to receive the detection-related data from the MCU, reanalyze magnetic field signal waveform data, and display a result thereof.

The magnetic field receiving unit may be configured to receive a pulse mode or a frequency mode.

The magnetic field receiving unit includes a single-channel magnetic field sensor for tracking the x and y coordinates, as well as a four-channel magnetic field sensor to identify the signal center between them.

In pulse mode signal reception, the input signal from the magnetic field receiving unit can be filtered using a bandpass filter to remove unnecessary power frequency components and harmonic signals and then digitally converted through an analog-to-digital converter (ADC) to detect whether a signal is present according to a cycle. Additionally, the input signal is processed by comparing it to a predetermined threshold and a signature (signal trains), and when the signature matches, it is determined that a transmitted signal has been successfully detected.

In frequency mode signal reception, the input signal is amplified in three stages, then amplified again after frequency filtering to tune into the transmitted signal frequency, and if the signal level passing through the tuning circuit exceeds the threshold, then convert it into digital through an ADC, and if it is determined that the signal has been detected after comparing whether the signature matches, display the signal value on the display.

### Advantageous Effects

1. In order to accommodate a polyphase power source, a transmitter may have the same number of commutation circuits as phases of the power source to deliver rectified output to a 3-level inverter to transmit the current pulse to the desired phase by switching according to the phase angle time of the phase selected to be transmitted without changing the physical connection.
2-1. In order to suppress an inertia action of a transformer, a DC_link unit including an accumulator between a converter and an inverter is provided so that an accumulator bears a high differential current at a start and an end of a current signal instead of a transformer, thereby preventing an inertia action of the transformer to limit the occurrence of a transient voltage.
2-2. In order to prevent magnetic flux from remaining and accumulating in the ferromagnetic components of a transformer due to a unipolar current, a dipolar (unbalanced voltage) or bipolar (balanced voltage) current pulse is generated from a three-phase full-wave rectification to eliminate any residual magnetic flux by a reverse polarity pulse signal.
2-3. In order to prevent resonance between the transmitter and the transformer, the accumulation means of the DC-link supplies (discharges) the high-differential current at the beginning of the current pulse; then, the cathode of the diode has a lowered voltage so that the transformer and the transmitter are forward-biased and electrically connected so that the transformer supplies a smooth current. At the end of the current pulse, the accumulation means absorbing the high-differential surplus current. Then, the increased voltage is supplied to the diode cathode to isolate the electrical connection between the transformer and the transmitter through reverse bias. Since the transformer inductor and accumulation means are operated independently, unexpected ferroresonance that may occur is effectively blocked.
2-4. The harmonic output limit regulation (IEC 61000 3-2) allows for an exceptive provision for power supplies that output a power of 75 W per phase. Accordingly, even when a high current is generated, in order for average power to be low, the high current is generated only at certain times in a discontinuous burst mode and is not generated for the rest of the time.

Being recognized as an exception to regulatory provisions allows the technology to expand the market for exploration technology.
2-5. In addition to a pulse mode, when a current pulse signal is transmitted using a frequency mode, a receiver is tuned according to a signal frequency to receive, amplify, and filter a signal and then process the signal when it exceeds a threshold. By using frequency modulation (FM) signals that prioritize a frequency as compared to amplitude modulation (AM) which places importance on the magnitude of a current pulse, signal distortion caused by noise is prevented in advance so that the transmission and reception of information are not disrupted.
3. Utilizing a 4-channel magnetic field sensor provides insights into the position of the power line between the left and right, as well as its burial depth.

Until now, power lines have been surveyed by applying a high current single-phase output signal using an unbalanced voltage to the power lines. In this case, there is a reason to move a transmitter position near a transformer and operate a transmitter, but there has been insufficient discussion about expected problems and solutions.

But in the present application, an unbalanced voltage source is used only in a limited manner when required to measure the voltage drop of a single phase power line or the polarity of a magnetic field signal by generating a current pulse near the transformer.

In addition, during the process of solving the problem, it was found that the holding time of a single burst current pulse signal could be divided into several smaller current pulses. When these segmented current pulses are transmitted, the frequency corresponds to the shortened holding time. This results in a higher transmission efficiency compared to transmitting a single pulse signal. Consequently, the method for transmitting current pulse signals was utilized in both pulse and frequency modes.

In addition, the differential mode is preferred over the common mode transmission method because it effectively reduces noise during the generation of a current pulse. This approach enhances reception characteristics with minimal current, eliminating unstable factors and ensuring safe operation, even when a current pulse is generated near the transformer.

In addition, in order for a receiver to receive a current pulse signal when the transmitter transmits the current pulse signal in the two modes, reception efficiency has been improved.

The purpose of IEC 61000 3-2 for limiting the inflow of harmonic waves and transient voltages into a public distribution network is to prevent in advance the instability of a system caused by the resonance of a transient voltage due to an inertial action of the public distribution network (transformer) caused by a high differential current signal.

Accordingly, a transmitter 10 should limit output power to fall within an exception provision of the harmonic wave limit for a public distribution network.

A transmitter includes a DC_link unit including an accumulator to prevent a nonlinear current to be transmitted from generating a transient voltage due to an inertial action of a public distribution network.

The transmitter allows the DC_link unit to have an appropriate reactive component value such that a rising edge of a nonlinear current pulse maintains a high differential characteristic (di/dt), thereby allowing receiver sensitivity not to be disrupted.

When a rising edge has a high differential characteristic for receiving sensitivity, a transmitter gradually reduces a falling edge, thereby suppressing surge voltage generation even in a low power factor environment with a Volt-sec balance.

A transmitter divides an existing nonlinear current pulse duty-on time (t) into ½f times and performs transmission such that a receiver may detect the presence or absence of a frequency f signal rather than a change in power density, thereby improving signal sensitivity despite pulse signal transmission.

A transmitter switches and controls a line-to-line voltage without a neutral voltage instead of a phase voltage with a neutral voltage of a public distribution network, thereby reducing common mode noise generation.

A transmitter divides the existing duty-on time (t) of a nonlinear current pulse into segments of ½f so that the receiver can detect the presence or absence of a frequency f signal rather than monitoring a change in power density, thereby improving signal sensitivity despite transmitting the low-current pulse signal.

When the transmitter transmits a nonlinear current pulse signal, the voltage fluctuations are measured at times excluding the rise and fall times of the nonlinear current pulse and are used as data for setting the appropriate supply or reception path of the public distribution network before connecting a large-capacity distributed energy resource.

The receiver is equipped with multiple magnetic field sensors and provides XYZ coordinates, including depth information.

### BRIEF DESCRIPTION OF THE DRAWINGS

FIG. 1 illustrates a configuration of a public distribution network.

FIG. 2 illustrates a buried path survey device for surveying power lines using a separate power source in the conventional technology.

FIG. 3 illustrates a configuration of the conventional technology current pulse generator.

FIG. 4 shows forms of linear and nonlinear current pulse signals.

FIG. 5 illustrates an example of a configuration with a power factor correction device.

FIG. 6 shows examples of current pulse signals before and after power factor correction.

FIG. 7 illustrates a configuration of a current pulse test room configuration including a variable power factor load.

FIG. 8 is a schematic diagram of a current pulse signal used during a test.

FIG. 9 shows waveforms of current pulses at a power factor of 81%.

FIG. 10 shows waveforms of current pulses at a power factor of 85%.

FIG. 11 shows an image of a waveform when a magnitude of level 5 is set.

FIG. 12 shows a transient voltage when a current pulse is generated when a transmitter is connected to a no-load transformer.

FIG. 13 shows a current waveform flowing in a low voltage line when a current pulse is generated.

FIG. 14 describes a voltage drop phenomenon when a switch is turned on.

FIG. 15 describes a voltage rise phenomenon when a switch is turned off.

FIG. 16 describes a reverse current phenomenon due to distributed energy resources.

FIG. 17 illustrates that distributed energy resources are prioritized and provided first.

FIG. 18 describes that a plurality of pieces of power are supplied when a current pulse is generated.

FIG. 19 shows a waveform of a transient voltage when a current pulse is generated.

FIG. 20 shows a change in waveform when a current pulse is generated.

FIG. 21 describes that line charging capacity flows in a line when a current pulse is generated.

FIG. 22 describes a received waveform according to line charging capacity as shown in FIG. 21.

FIG. 23 illustrates an accumulator that is an alternative for a transient voltage.

FIG. 24 describes that a DC-link unit includes an accumulator for suppressing a transient voltage.

FIG. 25 illustrates two separate closed loop circuits of a transmitter.

FIG. 26 describes transient voltage suppression when a switch is turned on by an accumulator.

FIG. 27 describes the transient voltage suppression when a switch is turned off by an accumulator.

FIG. 28 shows a change in transient voltage when capacity of an accumulator is changed.

FIG. 29 shows a comparison between transient voltage changes when a level is changed before and after an accumulator is installed.

FIG. 30 shows a comparison between transient voltage and low voltage line reverse currents before and after an accumulator is installed.

FIG. 31 shows current pulse signal modification by an accumulator.

FIG. 32 shows a change in received waveform by an accumulator.

FIG. 33 shows a waveform in which a current pulse signal amplitude is changed.

FIG. 34 shows a received waveform when a signal amplitude is changed as shown FIG. 33.

FIG. 35 shows that polarity is identified from a received waveform.

FIG. 36 shows a DC-link unit including a variable capacity accumulator.

FIG. 37 shows a waveform when a current pulse is sequentially turned off.

FIG. 38 shows an effect of a residual magnetic flux.

FIG. 39 illustrates a structure of a transmitter according to Example 1.

FIG. 40 describes the form of a unipolar pulse during three-phase rectification.

FIG. 41 shows a dipolar current pulse for resetting a residual magnetic flux.

FIG. 42 shows a waveform of a received signal of FIG. 41.

FIG. 43 shows various forms of current pulse waveforms.

FIG. 44 shows a pulse mode current pulse waveform.

FIG. 45 describes a voltage measurement stability section in a current pulse mode.

FIG. 46 describes an optimal power connection section setting by measuring a voltage drop.

FIG. 47 illustrates a basic structure of a receiver.

FIG. 48 shows a frequency mode current pulse signal.

FIG. 49 shows a waveform of a signal received by a signal of FIG. 48.

FIG. 50 describes a comparison between a pulse mode waveform and a frequency mode waveform.

FIG. 51 shows an example of actual waveforms in a pulse mode and a frequency mode.

FIG. 52 is a block diagram of a receiver having a function of receiving a pulse mode and a frequency mode.

FIG. 53 describes transmission through mixing of a frequency mode and a pulse mode.

FIG. 54 shows surge voltages in a pulse mode and a frequency mode.

FIG. 55 shows a received waveform in a pulse mode.

FIG. 56 shows a received waveform in a frequency mode.

FIG. 57 shows a comparison between a pulse mode and a frequency mode.

FIG. 58 describes a method of detecting a received waveform in a frequency mode.

FIG. 59 illustrates a screen on which a noise magnitude measured at a reception position is displayed.

FIG. 60 illustrates a screen on which a receiver sets left and right center points.

FIG. 61 describes a depth measurement waveform of a receiver.

FIG. 62 describes a depth measurement formula.

FIG. 63 illustrates a structure of a transmitter of Example 2.

FIG. 64 describes a bipolar current waveform after three-phase rectification.

FIG. 65 shows an optimal current pulse generation phase angle at a bipolar voltage after three-phase rectification.

FIG. 66 shows a waveform when a current pulse is generated at one phase angle (Z1) of FIG. 65 after three-phase rectification of the balanced voltage.

FIG. 67 shows a comparison between current pulse signals using unbalanced and balanced voltages.

FIG. 68 shows a comparison between current pulse signals using unbalanced or balanced voltages.

FIG. 69 describes that a wire disconnection fault detection system operates in an unbalanced voltage mode.

FIG. 70 describes that a wire disconnection fault detection system operates in a balanced voltage mode.

FIG. 71 shows a change in pulse during a transmission process.

FIG. 72 is a transmitter flowchart.

FIG. 73 is a receiver flowchart.

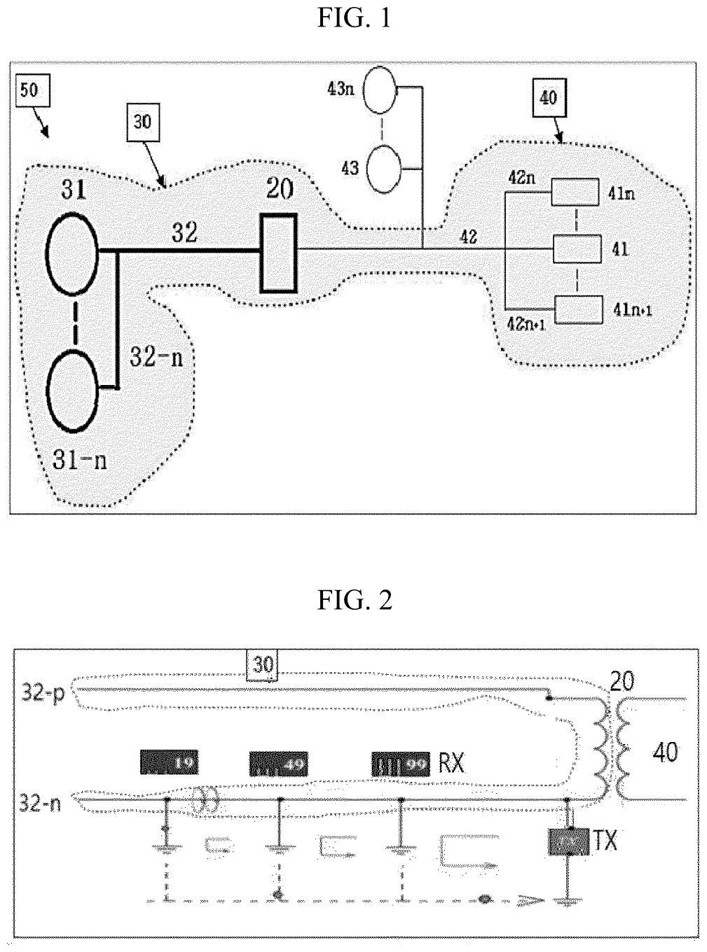

### DETAILED DESCRIPTION

### Best Mode

Provided is a method of surveying a power line by changing a pulse/frequency mode using a balanced/unbalanced three-phase voltage source and transmitting a current pulse signal to a public distribution network.

Provided is a device for surveying a power line by changing a pulse/frequency mode using a balanced/unbalanced three-phase voltage source and transmitting a current pulse signal to a public distribution network.

### Modes of the Invention

Many specific details are described in embodiments of the present invention. However, it should be understood that well-known circuits, structures, and techniques that might obscure the understanding of the present invention when describing the present invention are not shown in detail, but those of ordinary skill in the art, with the included descriptions, will be able to implement appropriate functionality without undue experimentation.

The term “public distribution network” used in the description of the present invention refers to a public power network with a voltage of 35 kV or less used for a public distribution network operator 70 such as DNO or DSO supplying (selling) or purchasing power, and in European regulations or the like, the public distribution network is further subdivided into a medium voltage section ranged from 1 kV to 35 kV and a low voltage section which has a voltage of less than 1 kV. In addition, unlike a private distribution network, such as a dedicated network, a public distribution network is one that anyone can access by paying a usage fee. A public distribution network, a low voltage section, and a medium voltage section are expressed differently as necessary but are all included in the public power network.

The term “current pulse signal” used in the description of the present invention refers to a discrete current signal that is distinguished from a general load current and is generated to be transmitted through magnetic coupling, wherein the general load current is used to connect a transmitter 100, which is a current conversion device, to a point of connection (POC), which is one point of a public distribution network, to track a power source configured to supply power to the POC or is used for a public distribution network operator to obtain information. Sometimes, the current pulse signal is referred to as a current signal, a current pulse, or a pulse signal, but is the same “current pulse signal.”

In the description of the present invention, an example in which a “polyphase power line” is a three-phase four-wire power source is described, but it should be understood that it does not mean that the polyphase power line cannot be applied to a single-phase power source as well as other types of polyphase power sources such as a two-phase or four or six-phase power source. In addition, for convenience of description or ease of understanding, an example of a single-phase is described, but it is well known to those in the same field that a polyphase (n-phase) may be constituted by combining n individual phases.

The reason why an example of the “public distribution network” in a public power network is described in the description of the present invention is because distributed energy resources (DERs) have been increasing mainly at a level of distribution voltage (35 kV or less). When power is supplied from a remote thermal power plant through a public transmission network (with a voltage of more than 35 kV), a current impulse signal reaches a thermal power plant which is a final power source that supplies a current, and thus, as a high voltage switching element technology advances in the future, when a current impulse signal is transmitted through a connection to a higher upper medium voltage network, the present invention will be applicable not only to a public distribution network but also to an upper public transmission network, and the scope of application of the present invention is not necessarily limited only to a voltage level of a public distribution network.

That is, the present invention provides an example in which a current conversion device expressed as the “transmitter 10” is connected to a low voltage section to generate a current pulse signal of up to 600 A and convert it into a 10 A medium voltage current pulse through a distribution transformer having a transformation ratio k of 60. However, the application of the present invention is not limited to the specific types of power networks or sections classified by the voltage level and current pulse classified by the magnitudes (A) provided as examples.

In the description of the present invention, the term “power line” is used to refer to the target receiving the current pulse signal or being surveyed. However, this term is not limited to just power lines themselves. It can also encompass devices such as transformers, switches, wiring devices, and distributed energy resources (DER) connected to a power line. Additionally, it includes locations where power lines pass, such as manholes, vault inlets, and pipelines.

In the description of the present invention, most of the description is made using the waveforms of current and voltage under the assumption that the voltage and current are in phase (power factor 1.0). However, in actual fields, the power factor may often be lower than that, so this should be taken into account.

In the description of the present invention, the use of recently developed voltage-driven power transistor switching elements such as metal oxide silicon field effect transistors (MOSFETs) or insulated gate bipolar transistors (IGBTs), which use SiC or GaN and are capable of being switched at a high voltage and a high speed, is exemplified, but it is not impossible to apply the present application technology to other current-driven switching elements.

In the description of the present invention, an example of an in-phase angle between a primary side and a secondary side of a transformer is described using a 5 Limb Yyn0 connection transformer that is advantageous for generating an unbalanced current. However, it is not impossible to apply the present application technology to a transformer with a different Limb and a configuration that causes a phase difference due to a difference in wiring method between the primary and secondary winding of a transformer.

In the description of the present invention, the application fields for “current pulse signals” include the exploration of power lines and the devices (such as power sources and loads) connected with them, as well as user authentication prior to connecting distributed energy resources (DER) to the public distribution network. However, the scope of the present invention is not limited to these areas. It can also be applied in fields such as energy trading, advanced metering infrastructure (AMI), and demand response (DR).

In the description of the present invention, the ferroresonance phenomenon is a phenomenon in which an unstable transient voltage occurs in a polyphase system rather than a monophase system of a public distribution network. In particular, the phenomenon may occur when an instantaneous unipolar nonlinear high current is generated in only one phase among three phases power system cited as an example in the present application, and thus an abnormal voltage may be generated.

In the description of the present invention, an application example in an operating environment where the earthing coefficient is lowered by multi-grounding (TN) the neutral point of a transformer to limit the voltage rise in healthy phases at the time of a ground fault. However, those in the same field will be able to fully understand that this does not mean that the present application technology cannot, unlike the example, be applied to a single grounding (TT) at the neutral point.

In the description of the present invention, the electrical inertia is an action of storing surplus generated power into a public power network, including the public distribution network, as reactive power and then first reacting to disturbances (faults or sudden changes in load current) and is a self-protection action of a public power network for suppressing sudden changes in current magnitude due to disturbances by reversely changing a voltage.

It should also be understood that the terms “coupled” and “connected (linked)” in the description of the present invention may be used together with derivatives thereof and are not intended to be synonymous with each other. Instead, in specific embodiments, the term “connected” may indicate that two or more elements are in direct physical or electrical contact. For example, the connection between the transmitter 10 and a low voltage line of a public distribution network 50 means the two entities are physically connected through a wire. On the other hand, the term “coupled” may mean that two or more elements are in direct physical or electrical contact with each other. However, the term “coupled” may also mean that two or more elements are not in direct contact with each other but still cooperate or interact. For example, a transformer 20 magnetically couples a medium voltage and a low voltage section but does not physically connect two different voltage sections. By the same logic, a receiver 11 is magnetically coupled to survey a power line without being connected to the power line itself.

The terms used in the description of the present invention have been selected as general terms which are widely used at present in consideration of the functions of the present invention, and this may be altered according to the intent of an operator skilled in the art or introduction of new technology. Also, in specific cases, terms are arbitrarily selected by the applicant, and the meanings of the terms will be described in detail in the corresponding description portions of the present invention. Therefore, the terms used herein should be defined based on the overall content of the present invention instead of a simple name of each of the terms.

Hereinafter, embodiments of the present invention will be described in detail with reference to the accompanying drawings so that those skilled in the art may easily practice the present invention.

A public power network is a structured system that transmits electricity generated at power plants to customers through a public transmission network and a public distribution network. Additionally, this network functions as a large synchronous pool, where power sources (generators) and loads are synchronized at a specific power frequency (fp) to facilitate the exchange of electricity.

The public distribution network 50 included in the public power network is managed by an electric operator, such as a distribution network operator (DNO) or a distribution system operator (DSO), and possesses grid inertia to handle minor faults and load fluctuations.

In general, a power converter is a device that converts an input of (1) alternating current or direct current (e.g., AC-DC), (2) frequency (50 Hz-60 Hz), or (3) phase into output by using forward or flyback conversion technology, and switches a voltage of the primary winding to output a converted voltage or current to a secondary winding through a magnetic circuit.

However, the public distribution network cannot control the voltage of transformer 20's primary winding like a typical power converter described above; therefore, it must continuously operate in an ‘on’ state without any power outages.

Accordingly, in the present application, in an environment in which a voltage of a secondary winding is always provided to a low voltage section 40 of the public distribution network through the primary winding of the transformer 20 of the public distribution network, a transmitter 10 is connected to the low voltage section 40 of the public distribution network to receive a voltage, and a switch 103 is controlled to be turned on/off at a low voltage network sinusoidal voltage phase angle time (impedance change) to instantaneously apply a low voltage network voltage to an internal resistor 102, thereby allowing a nonlinear current to be consumed.

That is, the transmitter (10) is supplied with a nonlinear current as a load from an unknown power source(s) connected to the public distribution network. In order to help understand that the transmitter is operated while consuming current as a load, it is sometimes described as “transmitting” a current signal to the public distribution network for better understanding.

When a transmitter (10) sends a nonlinear current signal, which includes information such as a signature or pulse group, this signal is then transmitted to a public distribution network. A receiver (11) can capture the magnetic field signal from any location before the source within the public distribution network and extract the information contained in it.

Current signals have disadvantages such as being slower than voltage signals and generating electromagnetic interference (EMI) noise, but when transmitted on power lines optimized for low frequencies below 100 Hz, they can accurately transmit and detect signals because they have less loss due to capacitive

In addition, there is an advantage in that a signal may be wirelessly received at a separation distance without electrical contact by the receiver, such as a magnetic field signal generated by a current signal that flows high voltage charged power lines.

It is a well-known fact that power supplies have two operating modes: continuous and discontinuous. Under normal loads, they operate in continuous mode (CCM, Continuous Conduction Mode), and under light loads, they operate in discontinuous mode (DCM, Discontinuous Conduction Mode).

In the present application, the transmitter generates a high current signal but should operate at low power to avoid causing any disruption to a system. Therefore, as shown in FIG. 4, a burst mode, in which a short-time pulse current is transmitted to the public distribution network, and a short-time high current signal, which is implied and has a time function, is transmitted only at a set time, is the most efficient DCM.

Recently, there has been a rapid increase in the number of Distributed Energy Resources (DERs) operating at a leading power factor to supply voltage to the low voltage section 40. As a result, a Point of Connection (POC) has been moved closer to the transformer to prevent the transmitter 10 from prioritizing current delivery from the DER over the public distribution network.

The transformer 20 should generate a nonlinear current pulse signal with a magnitude of at least several hundred amperes in a burst mode, taking into account that a voltage is reduced to 1/60 (400 V/22,900 V) during conversion to a medium voltage current.

In addition, when connected to the public distribution network to generate a current signal, a non-inductive pure resistance element is used for the internal resistance of the transmitter to generate rectangular pulse waves with high differential values during rising and falling.

The present application is an invention concerning a communication apparatus and method for safely transmitting a high-differential (di/dt) high-current signal without occurrence of the ferroresonance phenomenon caused by transient voltage to a power source (31) of a medium voltage section in the public distribution network with inertia as described above. A receiver inductively coupled with the power line receive the magnetic field signal accurately without noise effect transmitted by a transmitter (10) which low impedance coupled with the transformer connected to the medium voltage section.

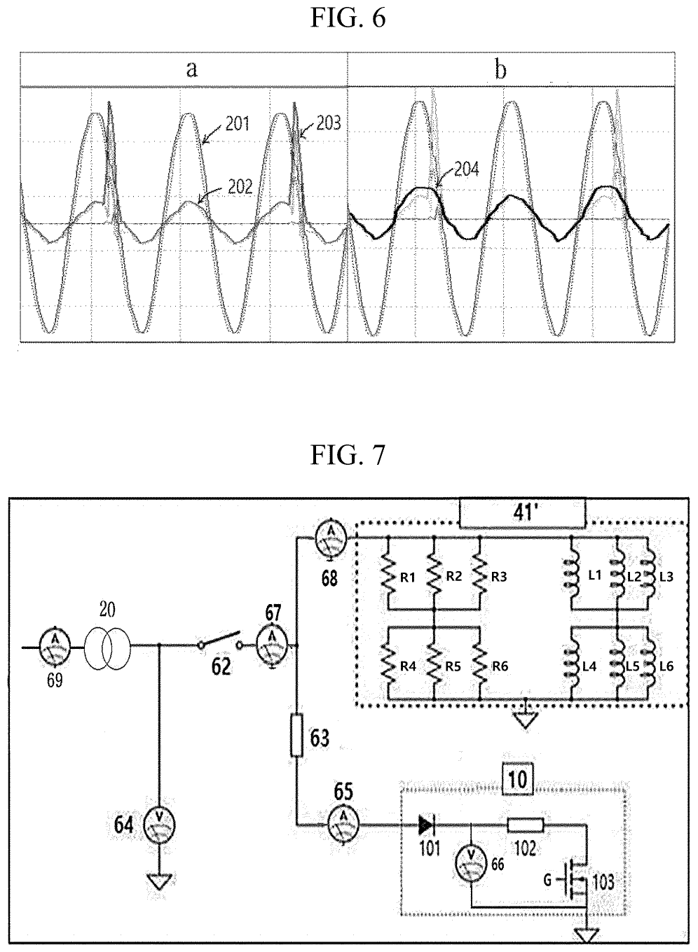

The IEC 61000 3-2 regulation suggested to limit harmonic wave emission is exceptionally applied for a low-power power source. In other words, in the case of a low-power power source having output power per phase of less than 50 W (currently less than 75 W, but planned to be limited to 50 W in the future), a current pulse signal 110 including a harmonic wave as shown in FIG. 6A may be transmitted to the public distribution network without the correction of a power factor (108) of FIG. 5.

FIG. 7 shows a test room equipped with a device where a transformer (20) provides power from a medium-voltage source 31 (not shown) of an actual public distribution network to a power factor adjustable load (41′) through the low voltage section. A transmitter (10) is installed parallel to the load at the point of connection (POC) to generate a current pulse signal. The study observed variations in this current pulse signal corresponding to the load's power factor changes. According to IEC regulations, the power magnitude per phase in a three-phase configuration is limited; however, a single-phase configuration is used here for convenience in description.

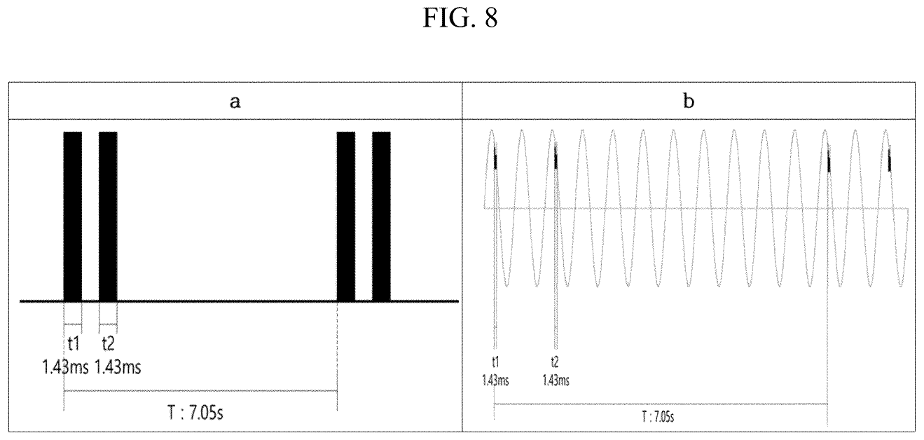

As shown in FIG. 8, the current pulse signal has a duration of t=1.43 ms and is set to be transmitted to the power source in the public distribution network by the pulse train generated twice at an interval by one cycle of the power frequency, a repeating total period of T is 7,050 ms.

In this case, a measured instantaneous current (A) value of the current pulse signal is used to calculate an effective current A (Iᵣₘₛ) and power P as follows.

$${I}_{rms} = A * root ( D ) = A * root ( t / T ) \qquad [ Equation 1 ]$$

$$P = ( {I}_{rms} ) \hat{} 2 * R \qquad [ Equation 2 ]$$

Here, a duty cycle D is calculated as follows with reference to FIG. 8 showing pulse time information.

$$D = root \{ ( t 1 + t 2 ) / T \} = root \{ ( 1.43 + 1.43 ) / 7 , 050 \} = 0.02 \qquad [ Equation 3 ]$$

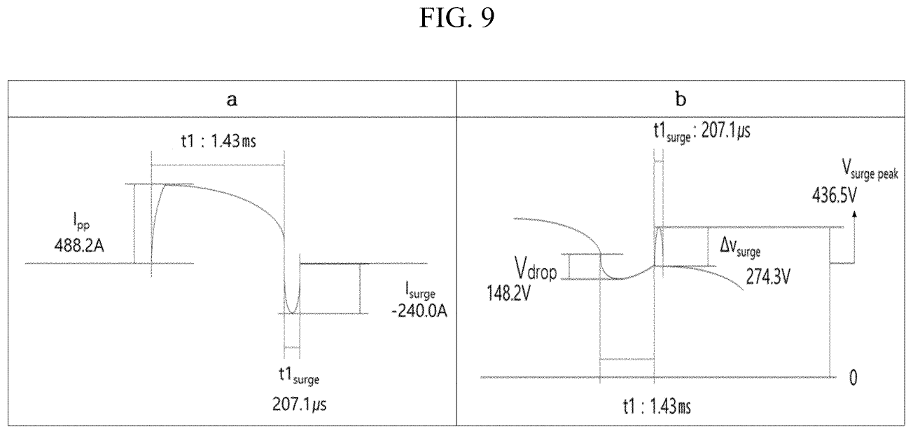

FIG. 9 shows waveforms of a current 65 of a transmitter 10 (see FIG. 9A) and a source voltage 65 (see FIG. 9B) when a power factor of the adjustable load 41′ is 81%.

In this case, effective current and power values are calculated as follows using Equation 1 and Equation 2. However, a value of a load resistor 102 of the transmitter 10 in FIG. 7 is 0.4Ω.

$${I}_{rms} = 488 ( A ) * 0.02 = 9.76 A$$

$$P = ( 9.76 ) \hat{} 2 * 0.4 ( ohm ) = 38.1 W$$

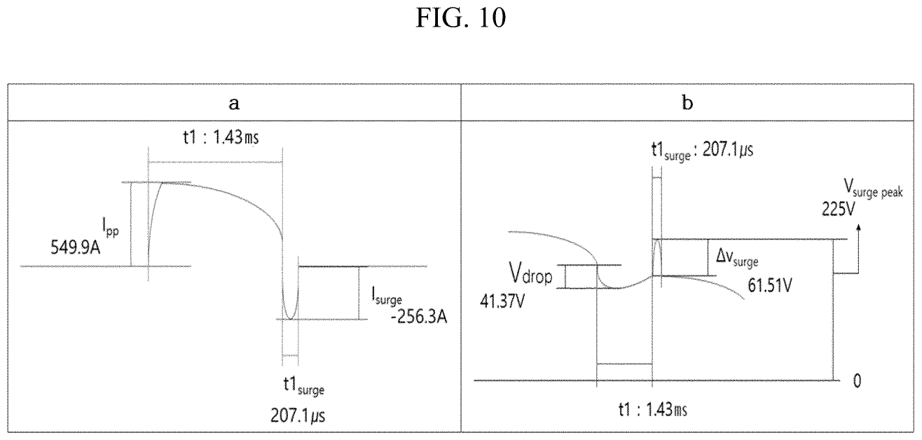

FIG. 10 shows waveforms of a current of a transmitter (see FIG. 10A) and a source voltage (see FIG. 10B) when a power factor is improved to 85% by the power factor adjustable load 41′.

In this case, an effective current and power are as follows.

$${I}_{rms} = 550 ( A ) * 0.02 = 11. A$$

$$P = ( 11. ) \hat{} 2 * 0.4 ( ohm ) = 48.4 W$$

Numerical values of test results of FIGS. 9 and 10 are compared as follows.

When a power factor is 85% (see FIG. 10), an instantaneous current value satisfies Iₚₚ=549 and I_{surge}=−256, and an instantaneous voltage value satisfies V_{drop}=41, V_{Surge}=225, Iᵣₘₛ=11.00, and power=48.4. When a power factor is 81% (see FIG. 9), an instantaneous current value satisfies Iₚₚ=488 and I_{surge}=−240, and an instantaneous voltage value satisfies V_{drop}=148, V_{surge}=436, Iᵣₘₛ=9.76, and power=38.1.

Summarizing these results, it can be seen that, when a power factor of the load 41′ connected to the transmitter 10 in parallel is improved, while an instantaneous value Iₚₚ, an effective value Iᵣₘₛ, and power of a current pulse signal increase, a voltage drop V drop and a surge voltage V_{surge} decrease. That is, when a voltage and a current are in phase, the power of the current pulse signal is maximum, and conversely, the voltage drop and surge voltage are minimum. Based on the above current and power calculation results, it can be seen that, in order to maintain output power of less than 50 W, a value of a current pulse instantaneous current A should be maintained less than 550 A. Accordingly, when an instantaneous current of 550 A is to be output from a sine wave with a maximum allowable voltage of 233 V (Vᵣₘₛ) [instantaneous voltage Vₚₚ of 329 V], a sine wave switching phase angle becomes 138° as follows.

$$A = [ V 138 ° = V max ( 329 V ) * sin ( 138 ° ) / 0.4 ( ohm ) * 1 ( PF ) ] = 550 A$$

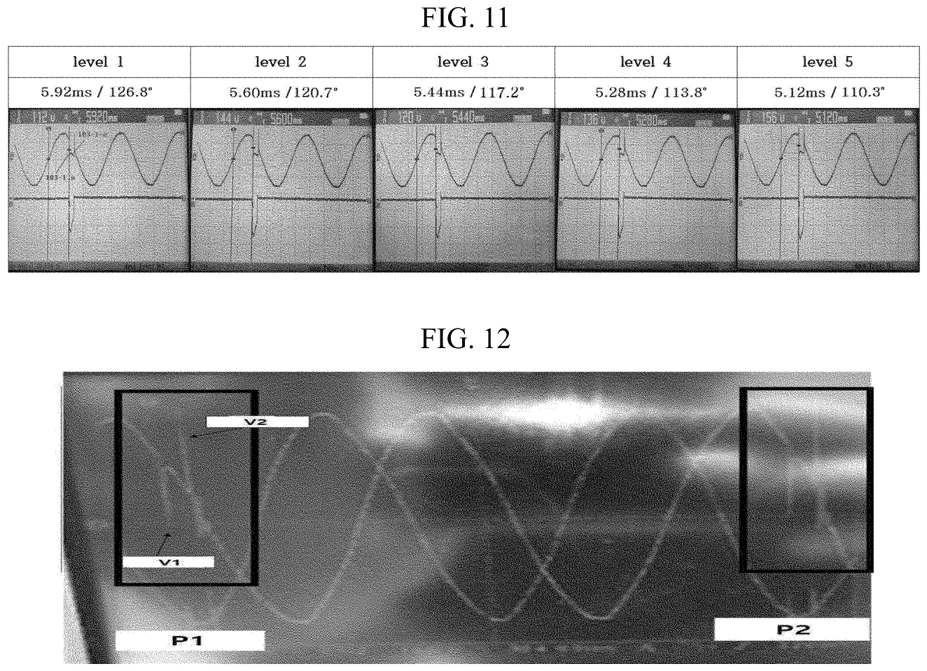

The maximum allowable phase angle is set to 138°, as indicated in FIG. 11. An additional 4-level value is utilized to transmit the current pulse signal. However, in contrast to the previously calculated value, the maximum current phase angle is set at 110.3° instead of 138° for operating the transmitter.

The actual voltage in the field is approximately 220V, which is lower than the maximum allowable voltage of 233V that was calculated earlier. This difference is noteworthy. Additionally, it can be observed that the magnitude of the current pulse signal gradually increases as the switching phase angle changes from the minimum current level of 1—which corresponds to a switching phase angle of 126°—to the maximum current level of 5.

When a transmitter transmits a current pulse signal to a public power network by limiting a switching phase angle to less than 50 W through such a method, the present application technology may be used to manufacture a fixed and continuously operated device such as a monitoring device rather than a temporary professional device, thereby operating the device without violating power quality regulations.

However, as shown in FIG. 9, there is a continuing problem in that a surge voltage of 436 V, which exceeds the maximum AC commercial voltage of 329 V when a load connected to the transmitter in parallel has a low power factor (81%), is leaked into the public distribution network.

When the transmitter 10 transmits a current pulse signal to a public power distribution network, in addition to the limitation of a power factor (including harmonic waves) according to IEC 61000 3-2, the regulations to be observed may be summarized as in Table 2.

In particular, when a unipolar nonlinear high current is continuously generated at the same phase angle of a sine wave, residual magnetic fields can be accumulated in the transformer core, which is made of ferromagnetic material. This accumulation may pose a risk due to the saturation of the BH curve. Additionally, when such a unipolar nonlinear high current is produced in Discontinuous Conduction Mode (DCM), the public distribution network, including the transformer, absorbs or releases reactive voltage to mitigate current fluctuations that occur at the beginning and end of the high differential current. This process can lead to voltage fluctuations (inertia), and in severe cases, it may even result in transformer ferroresonance.

The allowable maximum surge voltage (V) for inflow into the public distribution network must be less than the maximum surge voltage of DC 385 V. The reasoning behind this is as follows: 1. According to IEC 61643-11, the protection voltage for Line-Neutral (PEN) in a TN-C public distribution network is 255 V. 2. The protection voltage of a varistor (14D471K), which is used to protect the meter connecting the public distribution network to a customer facility, is rated at a DC voltage of 385 V.

An allowable change of the no-load current due to transformer core saturation should be less than 10% after a continuous transmission of unipolar current pulses for two hours. This guideline is based on an investigation into whether core saturation occurs as a result of residual flux when continuous half-wave commutation (unbalanced) current pulses are present.

In order to observe such a phenomenon in detail, FIG. 12 shows waveforms of a voltage drop V1 and an instantaneous surge voltage V2 included in a source voltage 65 generated when the transmitter 10 is connected to a low-load operation transformer to continuously generate current pulses P1 and P2 at a half-cycle phase angle of a sine wave having the same polarity at an interval of one cycle of a power frequency as in a time chart of FIG. 8A. Each pulse P1 or P2 has the voltage drop V1 when a switch is turned on to start a current pulse and the surge voltage V2 when the switch is turned off to stop the current pulse. FIG. 13 shows an enlarged diagram of a change in a low voltage line current 68 when the transmitter 10 generates a first current pulse signal P1.

When a switch of the transmitter 10 is turned on, it may be observed that, when the pulse P1 starts (V1), a current flow I1 is generated, and when the pulse P1 stops (V2), a waveform of a current flow 12 oscillates.

However, a measured current has a waveform measured by a magnetic field sensor which is used in a receiver 11, does not have an integrating function like a general ammeter (clamp meter), and is designed to detect a differential current as much as possible when a discontinuous signal (pulse) starts and stops.

It can be seen that, when the switch is turned on (V1), the current I1 drops once in a direction toward negative polarity 52 and then disappears while generating a vertical symmetrical wave, but when the switch is off (V2), a current I2 rises once in a direction toward positive polarity 51 to then no longer rise at a peak and undergoes high-frequency oscillation several times to then drop, and then while a center point 53 is lowered in the direction of the negative polarity to vertically oscillate asymmetrically, the current I2 is maintained longer than I1 and then disappears.

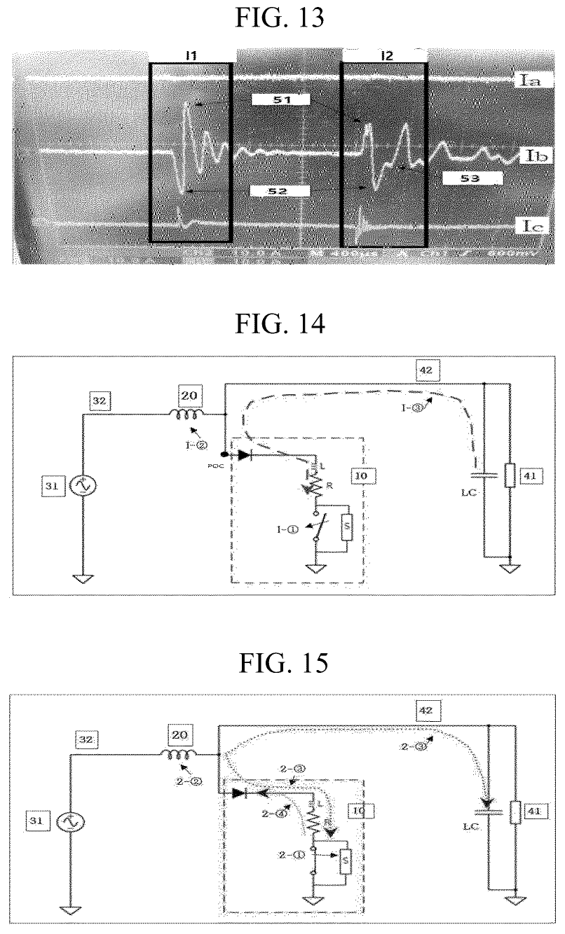

Describing such a phenomenon again with reference to FIG. 14B, in the transmitter 10 low-impedance-coupled to a distribution transformer 20, when a switch driving voltage is supplied to a gate 103-G (1-\textcircled{1}) in a duty-off (dead time) state in which a current does not flow through two ends of an internal switch, the two ends of the switch are electrically connected at a speed of tens of nanoseconds (dt), and thus a high differential current that rapidly increases from 0 A to hundreds of A (di) starts to flow. In this case, the electrical inertia of the public distribution network (transformer) acts to rapidly drop a transformer output voltage according to Equation 4 (1-\textcircled{2}).

$$v = - Ldi / dt ( V ) \qquad [ Equation 4 ]$$

When the transformer 20 absorbs a reactive voltage to suppress an increase in high differential current (di/dt) as in [Equation 4] and generates a reverse voltage V1 as shown in FIG. 12, instead of the transformer, a voltage of line charging capacity LC of a low voltage line 42 becomes higher than a transformer voltage, and thus a current is supplied to the transmitter 10 (1-\textcircled{3}).

However, although the voltage of the line charging capacity LC is indicated here on the low voltage line 42, this is for convenience of description, and those in the same field may easily surmise that the voltage may also be supplied from a medium voltage line 32.

For this reason, since I1 in FIG. 13 initially has a current with negative polarity 52, the line charging capacity LC supplies a current first, and after some time, the transformer charges the discharged current to return to normal.

In FIG. 15, conversely, when a maintenance time t of a current pulse P1 ends, a switch driving voltage of a gate 103-G is removed (2-\textcircled{1}) to separate two ends of a switch (off). In this case, when a flowing current of hundreds of amperes rapidly decreases to 0 A (−di/dt), transformer inertia releases a reactive voltage in a direction opposite to that of [Equation 4] to rapidly raise a power voltage (2-\textcircled{2}).

The rapidly raised voltage is distributed toward the transmitter 10 and a line to minimize a decrease in current (2-\textcircled{3}). However, a rising voltage passing through an internal converter (diode) of the transmitter 10 blocks a current flow between the transformer and the transmitter due to the diode being reversely biased, and thus, like a waveform of I2 of FIG. 13, a positive polarity current may no longer rise and may oscillate at a high frequency. In addition, a rising voltage trapped inside the transmitter may act as a shock to diodes or switching transistors, which may affect a lifespan (2-\textcircled{4}).

Thus, I2 of FIG. 13 initially has a positive polarity current once as the transformer raises a voltage at the moment when a transmitter current is blocked, but the diode of the transmitter allows only a unidirectional current to pass therethrough, and a voltage of a cathode gradually rises to interrupt a current flow and cause a vertical asymmetrical oscillation. In addition, regarding high-frequency oscillation occurring at an upper end of the positive polarity current generated once and persisting for a longer time, it can be seen that energy I2 generated when a switch is turned off is greater than energy I1 generated when the switch is turned on.

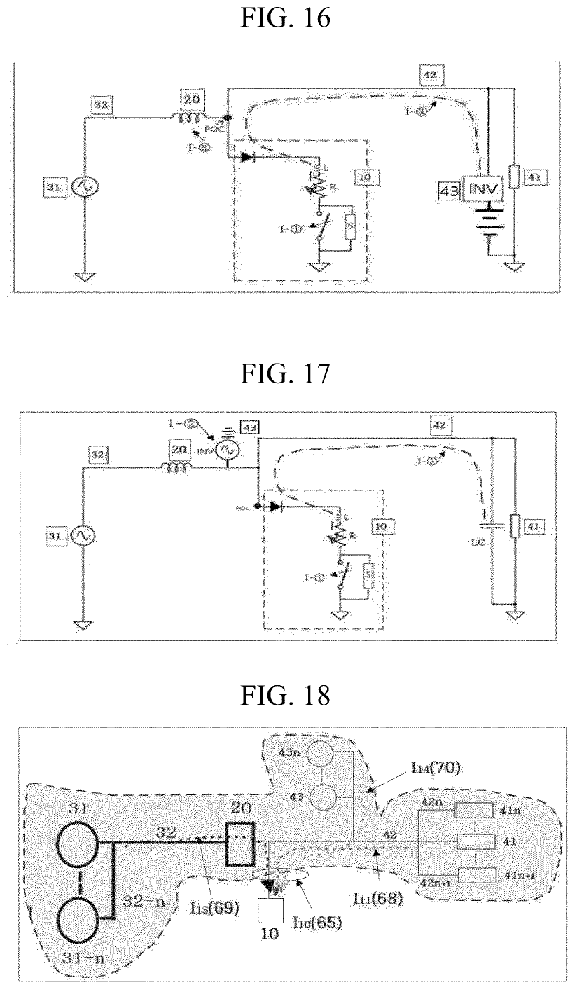

FIG. 16 describes that an inverter 43 that connects a DER to a public distribution network operates in a leading power factor and thus supplies a current to the transmitter earlier than the public distribution network. The DER serves as a power source with a capacity greater than the line charging capacity LC of FIG. 14.

Referring to FIG. 16 again, as shown in FIG. 17, the inverter is positioned in front of the transformer irrespective of distance so that a condition in which the inverter may supply a transmitter current with priority over the public distribution network is achieved.

FIG. 18 describes that a transmitter receives a current from a plurality of power sources connected to a low voltage section of a public distribution network.

Accordingly, the transmitter should be moved as close as possible to a transformer to receive more current from the public distribution network. Nevertheless, power is supplied from various power sources, including a high voltage current I13 (69) through a transformer 20 as well as a current I11 (68) of line charging capacity LC, and a current I14 (70) of the DER.

In addition, when a high differential current is generated in a load, although not as big as in a public power network, the inverter has a drooping characteristic to suppress a sudden change in current and thus operates as shown in FIG. 12.

Recently, as illustrated in FIG. 18, the use of distributed energy resources (DER) has increased. These resources are now being operated at a leading power factor to provide current to a public distribution network that includes power sources with high internal impedance. While the following explanation will focus on a transformer, it is important to note that this discussion also applies to distributed energy resources, such as inverters.

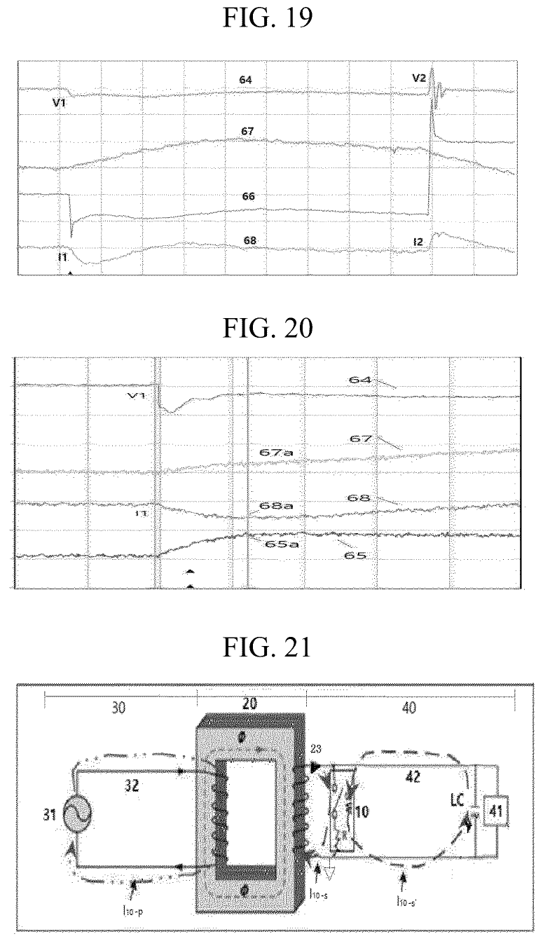

In order to confirm such an inertial action with an actual waveform, FIG. 19 shows changes in waveforms of a power voltage 64 of a public distribution network, a secondary current 67 of a transformer, an output voltage V+ (66) of an internal converter of a transmitter, and a low voltage line current 68 when a switch of a transmitter 10 is turned on/off. Here, for convenience, a voltage drop time V1 of the power voltage 64 is referred to as a switch-on time, and a surge voltage generation time V2 is referred to as a switch-off time.

At the time of V1, the power voltage at 64 and the output voltage, V+, of the converter decrease due to the inertia of the transformer. Additionally, the low-voltage line current at 68 flows in a reverse direction, similar to I1. However, the secondary current at 67 of the transformer is not significantly affected and gradually increases.

In addition, even at V2, the power voltage (64), the output voltage (66) of the converter, and the low voltage line current (68) all increase. However, it is observed that the secondary current (67) of the transformer decreases gradually, without the significant fluctuations seen previously.

That is, at the time V1, line charging capacity LC supplies a current to the transmitter and thus is consumed (discharged), and at the time V2, increased energy is absorbed (charged) by the line charging capacity LC. However, when a line does not have sufficient line charging capacity LC, or even the transmitter is blocked by an internal reverse voltage and thus cannot absorb any more increased voltage, a voltage raised due to an inertial action may apply shock to a public distribution network.

Again, in FIG. 20, instead of the output voltage 66 of the converter, the current 65 of the transmitter 10 is shown by enlarging a measurement waveform at the time V1.

When the power voltage 64 at the time V1 drops sharply in an almost linear direction, the low voltage line current 68 and the current 65 of the transmitter also fluctuate at almost the same speed until a time 65a when a power voltage returns to normal, but it can be seen that the current 67 of the transformer increases gradually in contrast. That is, it can be seen that the line charging capacity LC reversely supplies an initial current of the transmitter, and after the time 65a, the current 67 of the transformer bears the current of the transmitter 10.

FIG. 21 describes that, by using such a phenomenon, without a need to visit each low voltage customer 41 individually, when a transmitter is installed at a power source (transformer), and a switch is turned on (V1) or off (V2), the occurrence of a low voltage line current flow is detected to survey a low voltage line in which it is difficult to access a customer facility or of which a middle is cut due to demolition of the customer facility.

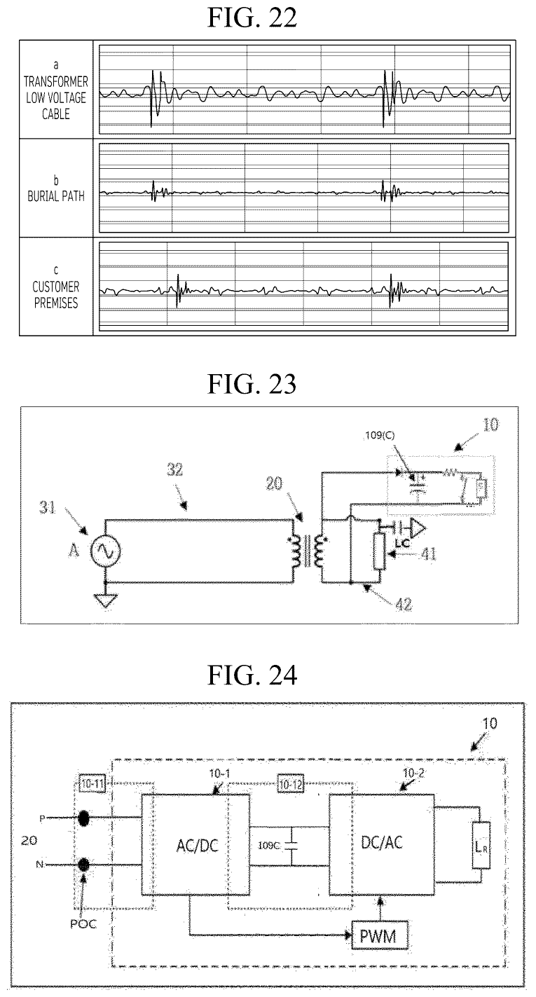

FIG. 22 shows waveforms of magnetic field signals received by a receiver 11 at three different positions at which a low voltage line is installed when a current pulse signal is generated in a configuration as shown in FIG. 21. FIG. 22A shows a received waveform around a transmitter 10, FIG. 22B shows a received waveform on a ground surface on a low voltage line-buried path, and FIG. 22C shows a received waveform in customer premises. However, the reason why a signal of FIG. 22B is relatively lower than the other two signals is because the signal of FIG. 22B is a signal detected on a ground surface that is apart from a buried low voltage line.

Returning again to a problem in which a surge (transient) voltage leaks to a public distribution network, considering this data, an “alternative component” that can replace line charging capacity LC is moved and installed near a secondary winding of a transformer to supply a current to the transmitter earlier than the line charging capacity LC (at a time V1) or absorb a surplus current (at a time V2) to ensure that the transformer does not recognize a sudden change in current, thereby minimizing the occurrence of voltage fluctuations of a public distribution network due to an inertial action.

FIG. 23 illustrates a configuration in which a transmitter 10 includes an “alternative component 109(C).”

FIG. 24 describes the interior of the transmitter 10 including the “alternative component” in FIG. 23 in detail.

The transmitter includes a connection unit 10-11 that receives a single-phase AC voltage at a POC which is a point of a public distribution network, a converter unit 10-1 that converts an input AC voltage into a DC voltage V+, and an inverter unit 10-2 that switches the output DC voltage V+ of a converter at a set phase angle time to allow a current pulse signal to be transmitted (flow) to a power source of the public distribution network through a pure resistive load L_{R}. Here, the inverter unit 10-2 includes the low-inductive pure resistive load L_{R}.

In the past, line impedance (inductance) was provided at a distance from a secondary side of a transformer to suppress a transient voltage, and in addition, as in a power factor correction component 108 of FIG. 5, due to the concern of the distortion of a current pulse signal waveform, in a transmitter, a separate DC-link unit did not include an accumulator.

When a DC-LINK unit (10-12) transmits the converter output to the inverter (10-2) without any modifications, the transmitted sine wave half-cycle voltage is PWM-controlled to exhibit a polarity similar to DC while its amplitude varies like AC, as illustrated in [FIG. 4b]. This results in a current pulse signal with characteristics of discontinuous, polarized discrete current being sent to the public distribution network. This allows it to be distinguished from the load current in the medium voltage section, even as it mixes with the load current through the transformer (20).

When the transmitter 10 is connected near a transformer and operated as a low impedance load, there is an advantage in that all generated signals may be transmitted to a power source of a public distribution network without line loss and without being distributed to distributed energy sources (DER).

However, when the transmitter 10 low-impedance-connected to the transformer stimulates the transformer with high inductance, the transformer inertially acts to release a voltage V2 or absorb a voltage V1 to the transmitter, thereby allowing a voltage to fluctuate and suppressing a change in current to be performed by the transmitter.

However when a low-impedance transmitter is connected to a high-inductance transformer and activates it, the transformer generates inertia that creates a voltage (V2) back to the transmitter while absorbing a voltage (V1) from it. This process alters the voltage and inhibits the current change that the transmitter is trying to produce.

The transient voltage may cause direct damage to the public distribution network or customer facilities, and also, electromagnetic noise may be generated due to the movement of line charging capacity.

To solve problems such as transient voltage generation and electromagnetic noise, an accumulator 109C which is an alternative component is provided in the DC_link unit which is positioned at the shorter distance between a converter and an inverter of the transmitter.

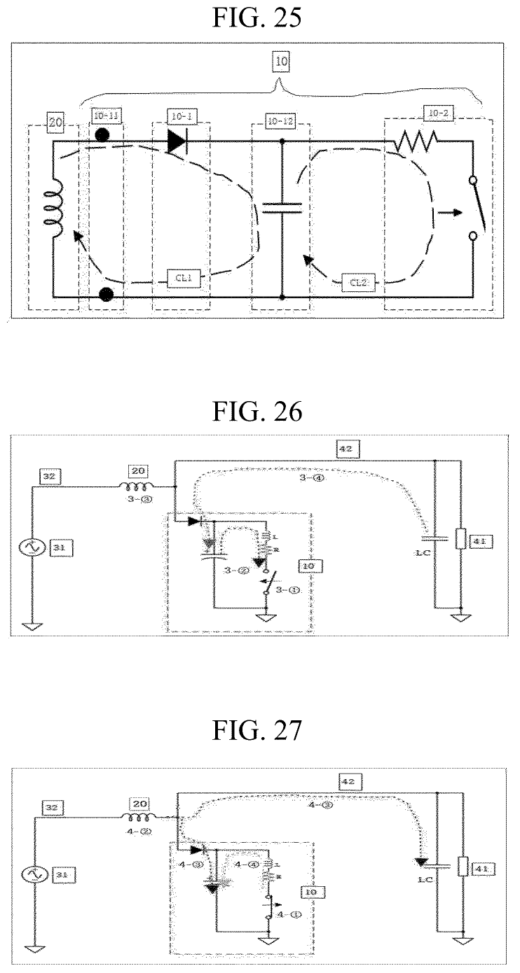

That is, as shown in FIG. 25, in transmitter 10, one terminal of a secondary winding of a transformer 20 is connected to a connection point 10-11 of a connection unit in series, a converter 10-1, and an accumulator of a DC_LINK unit 10-12, and the other terminal of the secondary winding of the transformer to constitute a first closed circuit CL1. In parallel with one terminal of an accumulator 109C of the first closed circuit, a load resistor of an inverter 10-2 and a series circuit of a switch are connected to the other terminal of the accumulator to constitute a second closed circuit CL2.

First, the first closed circuit (CL1) receives the low-voltage section voltage (V L) from the secondary winding of the transformer (20) and charges the DC-LINK (10-12) accumulator to the maximum voltage (root(2)VL) through the converter (10-1) that blocks reverse voltage. The second closed circuit remains OFF until a gate control signal activates the switch.

More specifically, as shown in FIG. 26, the accumulation means (109C) in the DC_Link unit serves as an “alternative means” to suppress the voltage drop at V1.

The accumulation means (C) in the DC_Link unit (the line charging capacity (LC) and the accumulation means (C) are at the same voltage (root(2) V L)), which is already charged to the maximum voltage of the public distribution network maintains the cathode (−) voltage of the converter (diode) at a higher voltage than the anode (+). That is unless discharged through the second closed circuit CL2, the accumulation means electrically isolating the secondary winding of a transformer from a transmitter due to a converter (diode) being reverse-voltage-biased.

In this way, the converter electrically separates the accumulation means (capacitance) in the transmitter from the transformer (inductance), preventing the formation of a circuit that could lead to the occurrence of a ferroresonance phenomenon.

In the described situation, when the switch of the inverter 10-2 of the transmitter is activated at a speed of several nanoseconds, it creates a second closed circuit (3-\textcircled{1}). the accumulation means 109C supply an initial high differential current to the inverter 10-2 (3-\textcircled{2}) before the converter is forward biased, and when a cathode voltage of the converter is lowered due to discharging, the converter is forward biased, and the transformer bears a current of the transmitter.

The accumulation means delivering an initial current that rapidly increases, followed by a gradual current from the transformer to prevent any inertial effects. This process results in a minimal voltage drop (V1) and significantly reduces voltage fluctuations (3-\textcircled{3}).

Reducing the transformer voltage fluctuation (V1) lessens the voltage difference between the line charging capacity (LC) and the transformer. As a result, the reverse current supply in the low-voltage line (3-\textcircled{4}) is also reduced, helping to decrease electromagnetic interference (EMI).

FIG. 27 describes that a surge voltage at a time V2 is reduced by an accumulation means C of a DC_link unit. When a switch of a second closed circuit is turned off (4-\textcircled{1}) to block a current while a transformer of a first closed circuit is supplying a current to a load of the second closed circuit, the accumulation means C, which is discharged at a time V1 and has a voltage lower than a maximum voltage, absorbs a surplus current that is being supplied by the transformer through a diode of a converter 10-1 (4-\textcircled{2}).

An initial surplus current with a large differential value is absorbed by the accumulation means to suppress the transformer from performing an inertia action and also absorb a surplus current, and then a voltage of a cathode (−) of a converter is increased to electrically separate the transformer in a reverse bias, thereby preventing a resonance phenomenon caused by possible transient voltage movement.

Accordingly, since a voltage difference between the transformer and line charging capacity LC does not occur, a current flowing through a low voltage line is minimized (4-\textcircled{3}) to reduce EMI. In addition, the accumulation means electrically separating the transformer from a transmitter so that shock to electronic components inside the transmitter is reduced (4-\textcircled{4}).

As above, when the DC_link unit between the converter and an inverter includes the accumulation means to suppress an inertia reaction of the transformer during the operation of the transmitter, it is possible to control a transient voltage not to be transmitted to a public distribution network.

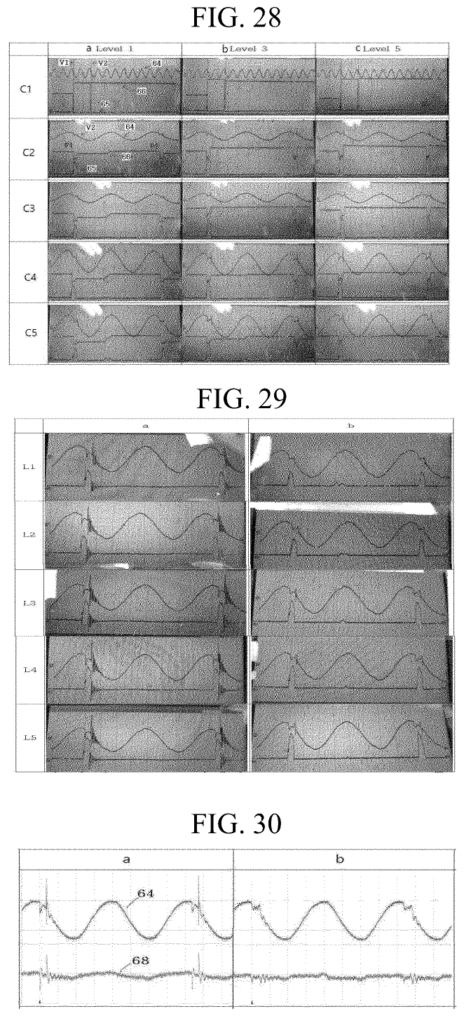

FIG. 28 shows that the capacity of an accumulation means of a DC_link unit of a transmitter is changed, and a voltage phase angle is controlled as shown in FIG. 11 to observe a relationship between a transient voltage V2 included in a power voltage 64 and an output voltage 66 of a converter according to a magnitude of a current pulse signal instantaneous value 65.

For the convenience of description, mainly describing a waveform 28c of a signal of level 5 with the largest instantaneous current value, it can be seen that capacity C1 causes a surge voltage of 1,000 V or more when there is no accumulation means as before. Although x and y axes of an oscilloscope screen cannot be zoomed out and viewed in detail to display an entire surge voltage on a screen, it is possible to first observe C2 in detail in which a magnitude of a transient voltage is reduced.

However, when the capacitance of the accumulation means continues to increase, it can be observed that a surge voltage V2 actually increases from C4.

That is, in C2 and C3, the accumulation means absorbing a surplus current at a time V2 to increase a diode cathode voltage to be reverse-biased to block the electrical connection between a transformer and a transmitter so that voltage is not introduced from the outside. However, when capacity increases, even when a surplus current at the time V2 is absorbed as in C4 and C5, the diode cathode voltage cannot increase, and thus the electrical connection between the transformer and the transmitter is maintained. Thus, a rising voltage is introduced from the transformer.

FIG. 29 shows a waveform of a transient voltage generated when a current pulse is generated through a connection to a no-load transformer by using an accumulation means with two different capacitor values. It can be seen that the surge voltage when the switch is turned off (V2) is significantly higher than the surge voltage when the switch is turned on (V1), and even when the accumulator is provided, a transient voltage increases in proportion to the magnitude of a current pulse.

FIG. 30 demonstrates that the waveform of a surge voltage (V2) present in a source voltage (64) correlates with the waveform of a low voltage line current (68) when a current pulse is generated, depending on whether the transmitter includes an accumulation means. As illustrated in FIG. 30B, when a DC link unit incorporates an accumulation means with suitable capacity, it can be observed that not only is the surge voltage V2 minimized, but the current (68) flowing through the low voltage line is also reduced. This reduction helps to mitigate electromagnetic interference (EMI) phenomena.

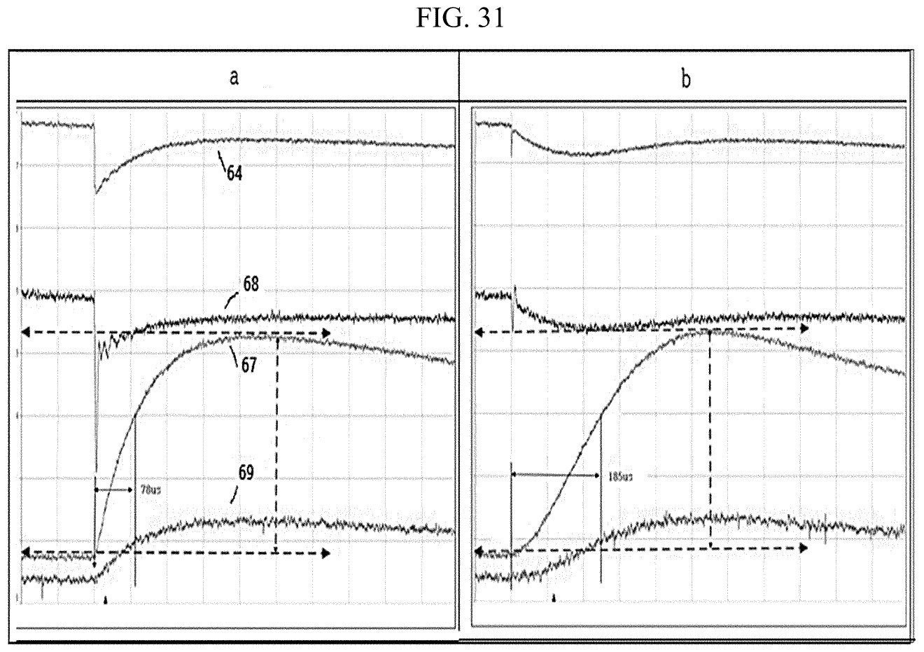

FIG. 31 illustrates the comparison of the time taken for the secondary current (67) of a transformer to reach 63% of its maximum current using different accumulation means. In the case of an accumulation means with lower capacity, as shown in FIG. 30A, the arrival time is 78 μs. However, when an accumulation means with higher capacity is used, as depicted in FIG. 30B, the arrival time increases to 185 μs. This shows a delay of twofold or more in preventing transient voltage generation.

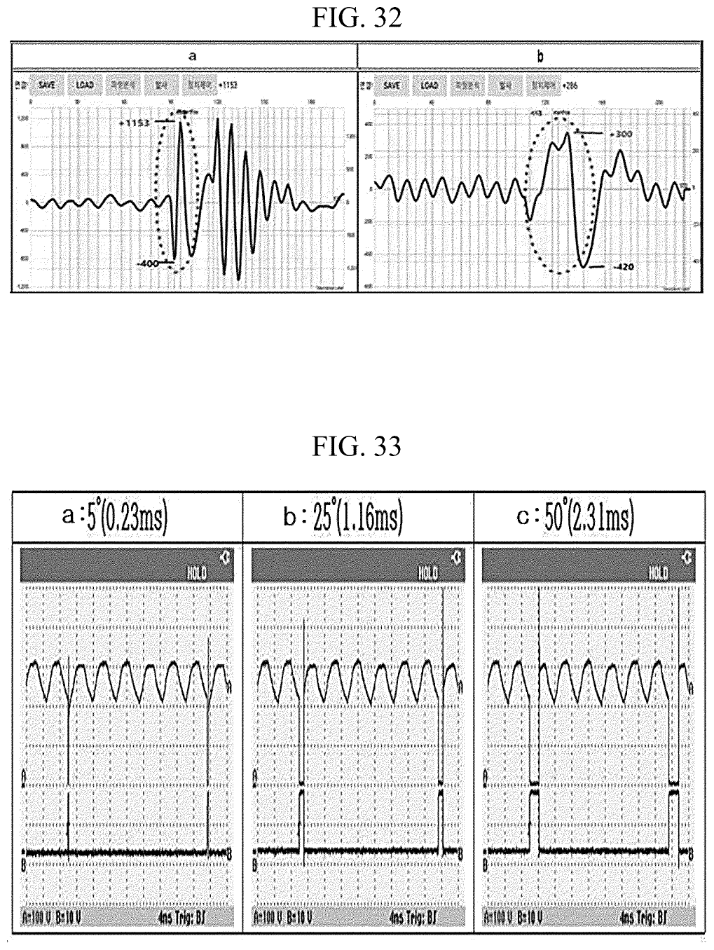

FIG. 32 shows a comparison between signal waveforms detected by a receiver 11 when a pulse current rising speed changes by a C constant of an accumulation means in a DC_link unit as shown in FIG. 31. Referring to FIG. 32A, it can be seen that, when a signal of FIG. 31A is transmitted, the magnitude of a received signal is a maximum magnitude of 1,153, but when a signal of FIG. 31B is transmitted, a signal is received with a value of up to about 300, which is reduced to ¼ of that in FIG. 32A.

To summarize again, the transmitter 10 has an advantage due to its DC link unit, which incorporates an accumulation means between the converter and the inverter. This design allows the system to provide both surplus and insufficient currents when a current pulse is generated, helping to suppress transient voltages (V1 and V2) and electromagnetic interference (EMI). However, the capacitance in the system can reduce the differential (di/dt) characteristics of the current pulse signal, resulting in situations where the receiver may not be able to detect the current pulse signal.

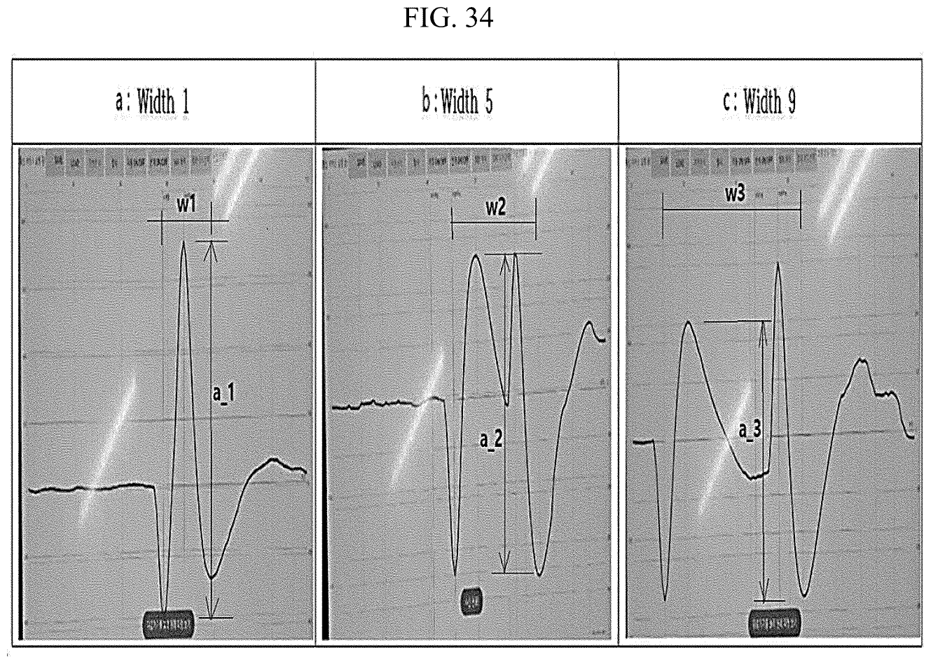

In addition, FIGS. 33 and 34 show waveforms detected by receiver 11 at the same location while transmitting current signals with three different pulse widths. This helps to identify the impact on the receiver when using an accumulation means, as shown in FIG. 32B, particularly as the width of the current pulse signal (the pulse duration time of t) is increased.

FIG. 33A shows a current pulse signal with a width W1 of 0.23 ms at stage 1 transmitted by a transmitter, FIG. 33B shows a current pulse signal with a width of 1.16 ms at stage 5 and FIG. 33C shows a current pulse signal with a width of 2.31 ms at stage 9. The current pulse width used in previous examples is 1.43 ms, as depicted in FIG. 8, which is very similar to the width of 1.16 ms of the pulse signal in FIG. 33B, which is six times wider than the signal in FIG. 33A and half the width of the pulse in FIG. 33C.

FIG. 34 illustrates a comparison of waveforms of received signals with varying widths, as shown in FIG. 33. A transmitter sends signals that have the same switch-on phase angle time and current value but differ in their pulse duration time of t, all at the same point of control (POC). In this scenario, the receiver indicates a higher measurement value when it receives a waveform with a narrower pulse width.

That is, while a signal of FIG. 34A with a frequency of about 2.2 kHz due to a short signal pulse maintenance time falls immediately from a peak of a received rising signal and a signal amplitude is large, a signal of FIG. 34B with a frequency of 400 Hz shows that a rising signal falls to a middle level from a section in which there is no differential value (upper flat portion of a pulse wave) and then a falling signal is received, and a signal of FIG. 34C with a frequency of 200 Hz falls to a middle level and then has a lower value due to a falling signal being received.

That is, until now, a current pulse signal has been generated by phase angle modulation of a low-voltage section's sinusoidal voltage, as illustrated in FIG. 11. The power density can be adjusted by modifying either (1) the signal magnitude (amplitude) or (2) the duration of the current pulse (duty ratio). Therefore, it has been discovered that low-power transmission can be achieved by minimizing the width of the current pulse.

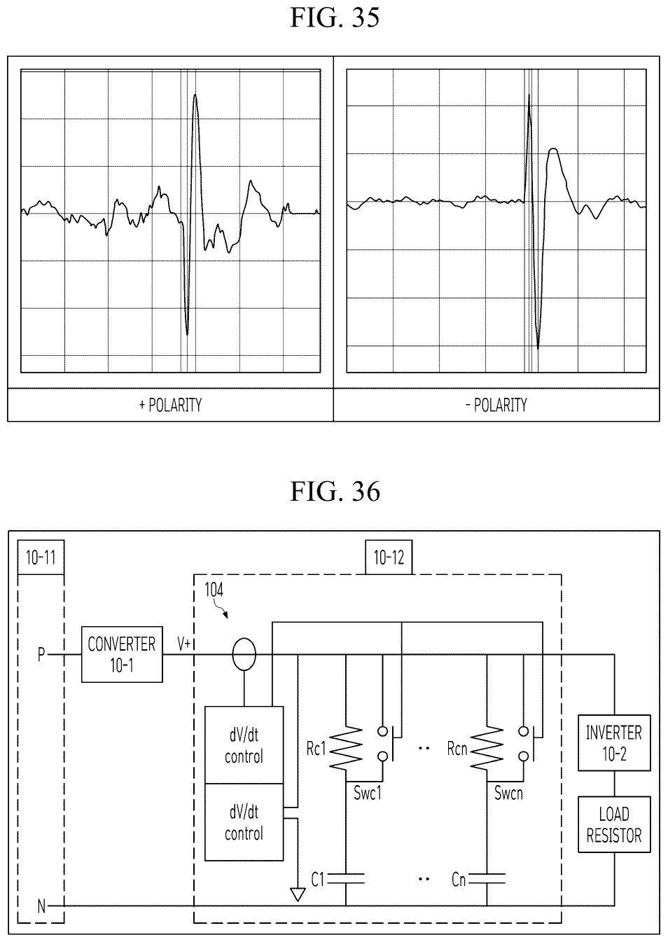

FIG. 35 shows a waveform in which a receiver identifies polarity when a current pulse signal has a pulse width of which a duration time t is similar to that in FIG. 34A is transmitted. FIG. 35A shows a waveform that falls from a waveform start point in a negative polarity direction and then has a larger rising width in a positive polarity direction. Initial falling in a negative polarity direction is caused by a voltage drop that occurs at a time V1, which generates an opposite polarity magnetic field, but immediately, rising in a positive polarity direction to a larger value is caused. When such a waveform is received, it is determined that the waveform denotes a power source direction (+) in which a current is supplied.

Of course, when the accumulation means in a DC-link unit compensates for V1, the initial negative polarity waveform may not be present.

Conversely, as illustrated in FIG. 35B, a waveform that begins to rise in the positive direction and then quickly falls with a greater width in the negative direction indicates a load direction (−) in which current is being received.

Likewise, an initial positive polarity direction waveform may not appear.

In this way, polarity can be determined using only a waveform of a wave head of a received signal, and it can be seen that when the duration time t of the remaining wave tail is short, the amplitude of an entire signal increases.

Referring to FIGS. 34 and 35, it can be seen that the receiver can easily detect the initial starting point of a current pulse signal, which is a non-modulated waveform, and also that the leading edge of the wavefront of the signal must have a high-differential characteristic and polarity without deformation in order to determine the polarity of the current pulse flows.

FIG. 36 illustrates that when a transmitter generates a current pulse signal in an environment where transient voltages may arise-often due to frequent changes in the power factor of a load connected in parallel to a transformer—the capacity of the accumulation means in a DC_Link is adjusted to mitigate the formation of transient voltages, such as V1 and V2.

In FIG. 19, the output voltage waveform (66) of a converter shows that at time V2, a transient voltage is generated with an amplitude at least three times greater than that observed at time V1. This means that by monitoring the amplitude of the voltage drop or the rate of change of voltage (dv/dt) at time V1, we can predict the magnitude of the voltage rise at time V2.

In addition, by measuring a voltage drop (V1) of a power voltage 64 in FIG. 9B or 10B, a voltage rise (V2) may be expected.

Accordingly, the output voltage 66 of the converter and a differential value or a fluctuation value of a current are measured to control a switch Swc to apply appropriate capacitance to a DC_link unit.

Although not shown in the drawings, it is clear that appropriate charging capacity may be adjusted by measuring the power voltage 64 and a current.

However, as shown in FIGS. 31 and 32, while an accumulation means can reduce the voltage V2, it also decreases the differential value. This reduction leads to a notable decline in reception sensitivity due to a delay by signal width (expansion).

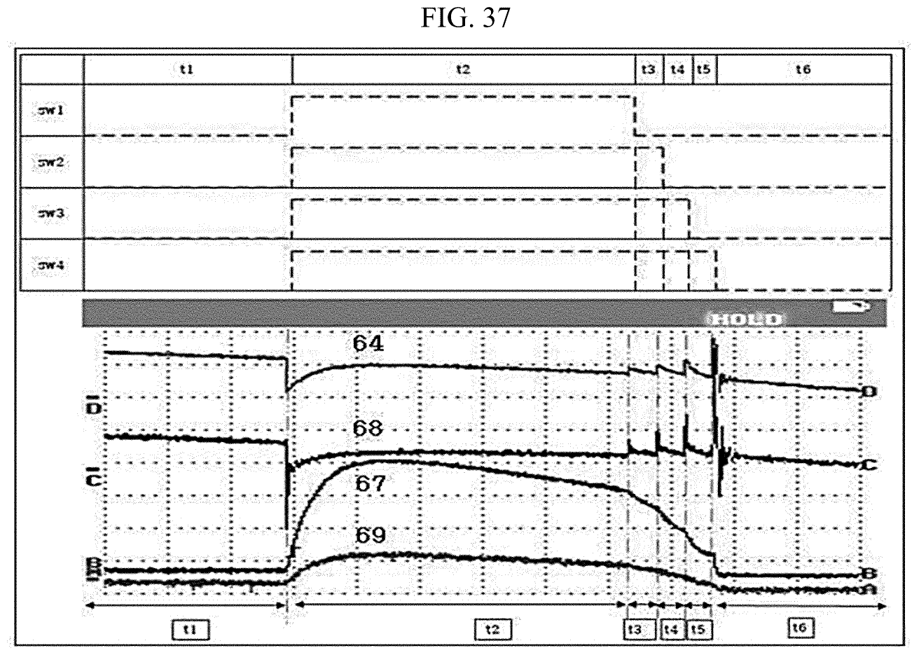

Accordingly, to ensure accurate reception of a current pulse signal transmitted in baseband without modulation, as little of the capacity of the accumulation means as possible should be applied to the DC_link unit. This approach allows the receiver to accurately receive the current pulse signal without any noise interference. Additionally, to prevent potential issues, such as a voltage spike at time V2, the current is gradually divided into three segments at times t3, t4, and t5, as shown in FIG. 37, effectively blocking the pulse current.

That is, in an environment like the one shown in [FIG. 19], it can be observed that when the pulse current is not blocked all at once at the V2 time but is instead blocked gradually in three stages, the increase in V2 voltage is significantly reduced.

FIG. 37 shows a waveform when a DC_link unit does not use an accumulation means, as shown in FIG. 19, and pulse current sequential blocking is used at a time V2, but when an accumulation means in FIG. 36 is controlled to use minimum capacity, and it is expected that it may be further improved.

A low voltage section of a public distribution network can have both balanced and unbalanced voltages. Unbalanced voltage refers to a situation where the neutral point of a power line is multi-grounded (TN) to increase line fault current, thereby making detection easier. This combines the phase voltage with the neutral line voltage of a single-phase supply. In contrast, balanced voltage refers to a scenario where only line-to-line voltage is present, without a neutral line.

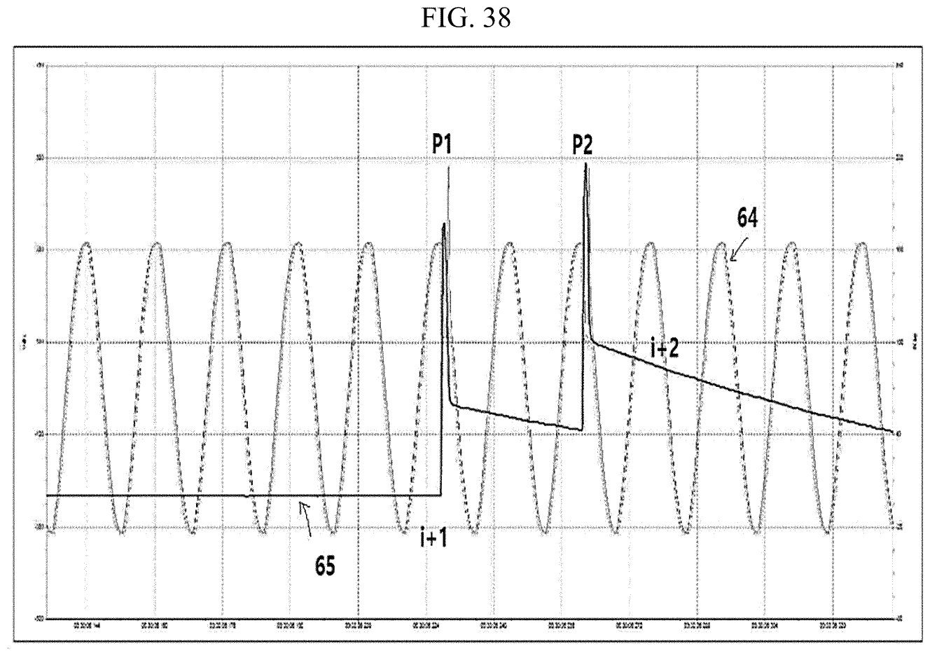

In the previous examples, a current pulse is generated during a half cycle of an unbalanced sinusoidal voltage using a neutral line to determine polarity. Through this transmission method, a receiver can identify the direction of power or load flow. However, a residual magnetic field may be created due to the generation of unipolar current, as illustrated in FIG. 38. A voltage increase occurs at time V2t because of a Volt-second imbalance caused by the residual magnetic flux. Additionally, when a BH loop is not formed, residual magnetic flux can accumulate, leading to adverse effects such as transformer saturation.

### Example 1

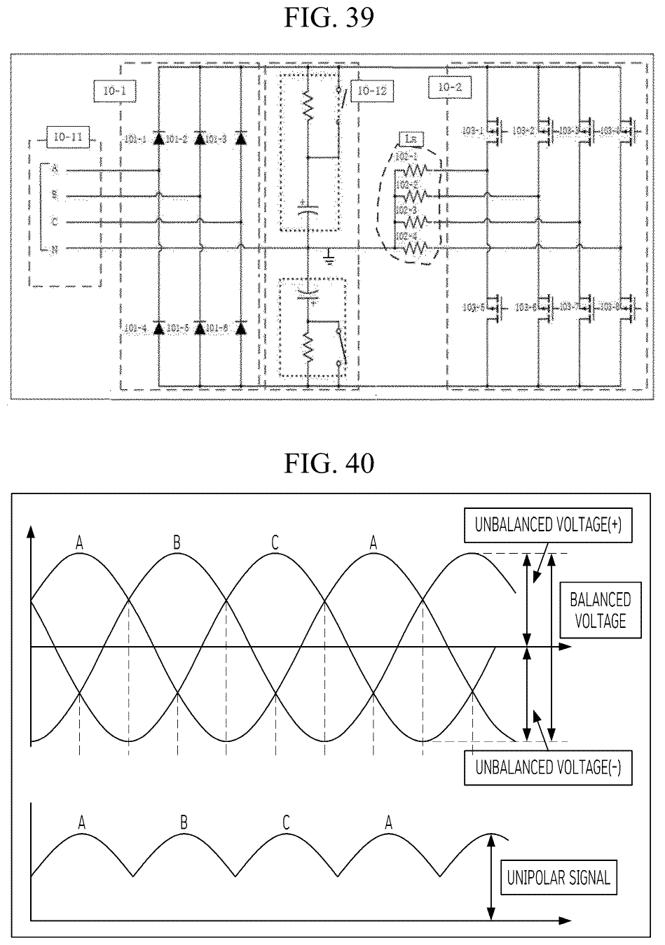

FIG. 39 shows a transmitter that generates a current pulse signal using an unbalanced voltage (phase voltage) using a neutral line.

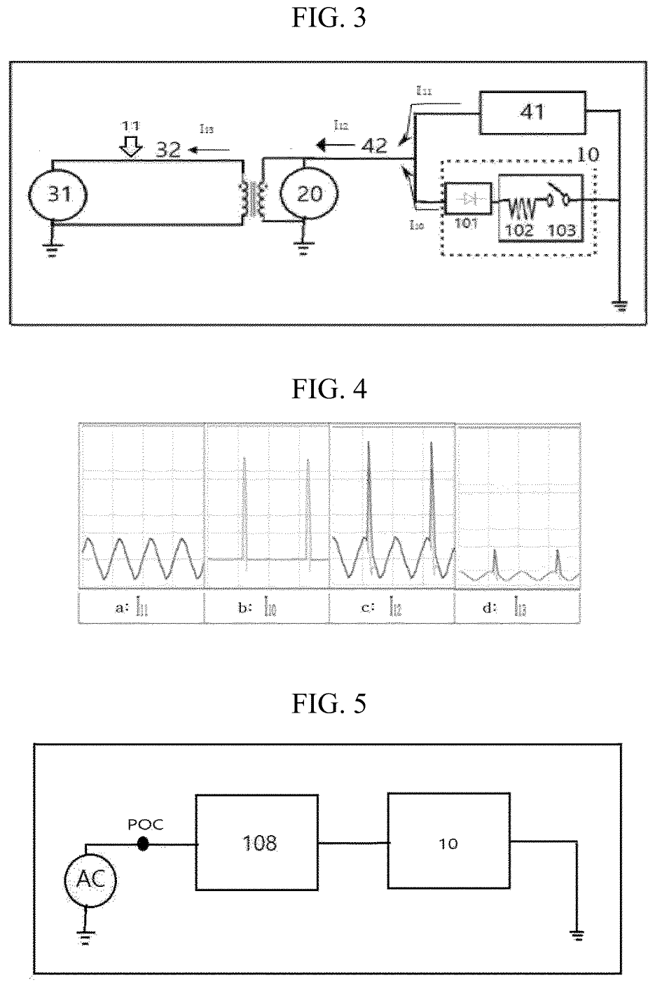

In conventional technology, the transmitter is designed to receive a single-phase voltage, as illustrated in FIG. 3, and outputs a unipolar current pulse signal of the same phase. However, in Example 1, the transmitter is configured to receive three-phase input power, performing full-wave rectification. It selects one phase from the three and outputs a signal to that selected phase and the neutral line at half-cycle intervals.

For example, consider the case of the (+) polarity output shown in [FIG. 40]. When a frequency of 60 Hz is applied, the rectifier generates an output voltage of 180 Hz, which is three times higher. This means that the rectifier produces a voltage for 120° for each phase with (+) polarity. When switching occurs in accordance with the timing of the phase voltage being output, a unipolar current pulse signal is transmitted between the corresponding phase and the neutral line.

Switching is performed such that, after a half cycle (180°), a negative unipolar current pulse signal with opposite polarity is transmitted to a phase to which a positive polarity current signal is transmitted as described above. Two unipolar current signals with opposite polarities are transmitted in a 180° phase angle cycle to transmit a dipolar current pulse.

In addition, the DC-link unit has an accumulation means, and although not shown, it also has a control means that can select an appropriate capacity, as shown in [FIG. 36].

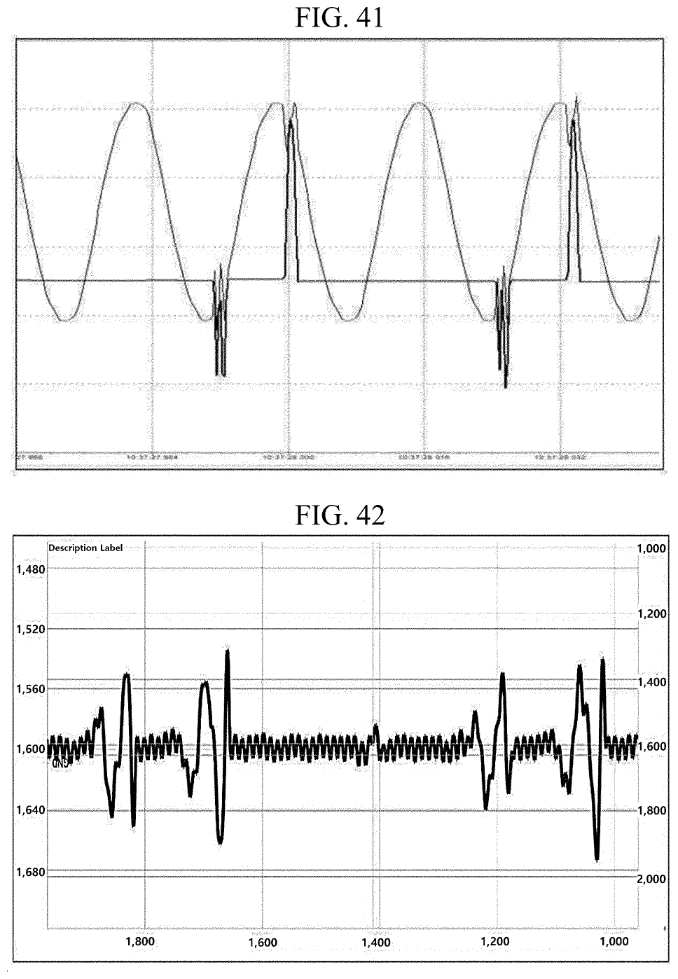

FIG. 41 illustrates the solution to the instability issue caused by the shifting reference point of current measurement, which occurs due to the residual magnetic flux of the transformer when transmitting a unipolar current pulse signal, as shown in FIG. 38. Instead of using a unipolar pulse, a dipolar pulse signal consisting of both positive and negative currents is transmitted at intervals corresponding to the half-cycles of a sinusoidal voltage. Unlike [FIG. 38], the reference level of the magnetic field signal from the current pulse remains stable, as the residual magnetic flux has been eliminated.

FIG. 42 illustrates the signal detected by the receiver when dipolar current pulse signals, as shown in FIG. 41, were transmitted. The negative current pulse signal, intended to balance the voltage (Volt-sec) applied to the transformer winding, was transmitted in several smaller pulses to differentiate it from the positive current. In contrast, the positive current pulse signal was transmitted as a single, larger pulse.

Upon reviewing the results above, it is evident that polarity information can be identified even when utilizing several small current pulses (negative polarity) that have a shorter duration than the overall time (t). This is similar to using a continuous positive current pulse, which generates current for the entire duration of the pulse signal (t).

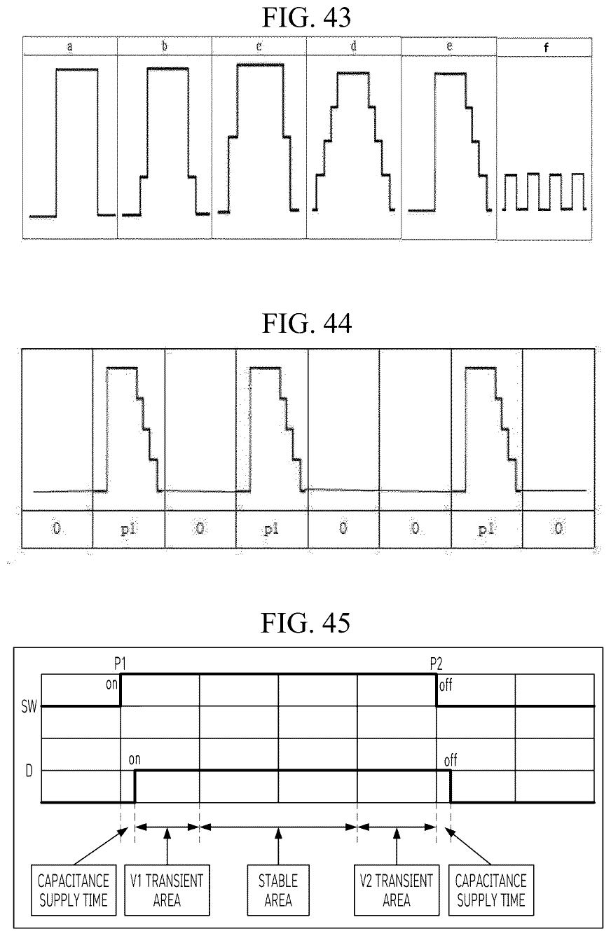

FIG. 43 shows the forms of current pulse signals that may be transmitted by a transmitter. FIG. 43A illustrates a scenario where a signal indicates that current flows during the pulse duration time t, which has been referenced in previous examples, including the positive current pulse signal shown in FIG. 42.

FIGS. 43B, 43C, and 43D illustrate cases in which a signal is generated by adjusting (either increasing or decreasing) the start and end of a current pulse across multiple levels. FIG. 43E illustrates a case where a signal is generated that shows a decrease in voltage V2, as depicted in FIG. 37. In this instance, the head of the current pulse signal remains unchanged, while the tail of the signal gradually decreases over time. FIG. 43F illustrates a scenario where multiple current pulse signals are generated, creating a train of small current signals with a pulse width of 2 kHz, similar to the negative polarity current pulse signal depicted in FIG. 42. However, as shown in FIG. 43F, the receiver has been interpreting the series of small current pulse signals as a single signal. This interpretation is based on detecting the overall magnitude of the signal and comparing it to a predetermined threshold value, as FIG. 43A. This approach is taken despite the fact that the series of signals has a specific frequency.

FIG. 44 describes that a high current pulse signal with polarity is transmitted at a cycle interval. As described above, for signal reception, only a tail is modified and transmitted without modification of a head. Continuously transmitting a high current pulse signal as described above is not only for the purpose of polarity determination but can also be used to measure a voltage drop in each low voltage network section of a public distribution network when an instantaneous current signal is transmitted.

When connecting a high current load, such as an electric vehicle, to unknown power sources in the low voltage section, it can be helpful to first generate a high current pulse signal. This pulse signal will allow you to determine the optimal route for connections. By measuring the voltage drop in the middle section as the signal reaches each power source, you can identify which section has the minimum voltage drop. Once identified, this section can be selected to configure the system in advance for a more efficient current reception.

FIG. 45 illustrates a stable area where a voltage drop can be measured when a current pulse signal is transmitted. Specifically, when switch SW is turned on (P1), a period follows during which a charging current is supplied to a load by an accumulation means. During this time, the cathode voltage of diode D decreases, which results in it becomes forward-biased and electrically connecting the transformer to the transmitter. Subsequently, it becomes possible to measure the voltage drop in the power source side of a public distribution network at a point where a stable current is supplied, following a transient period (V1) during which the transformer increases the supply current.

When the switch is turned off at time P2, marking the end of a current pulse, an accumulation means absorbing the surplus current. This causes the voltage at the cathode of the diode to increase, placing it in a reverse-biased state. As a result, the transformer is electrically isolated from the transmitter, preventing any further external voltage from rising and blocking unnecessary resonance between the inductance of the transformer and the accumulation means.

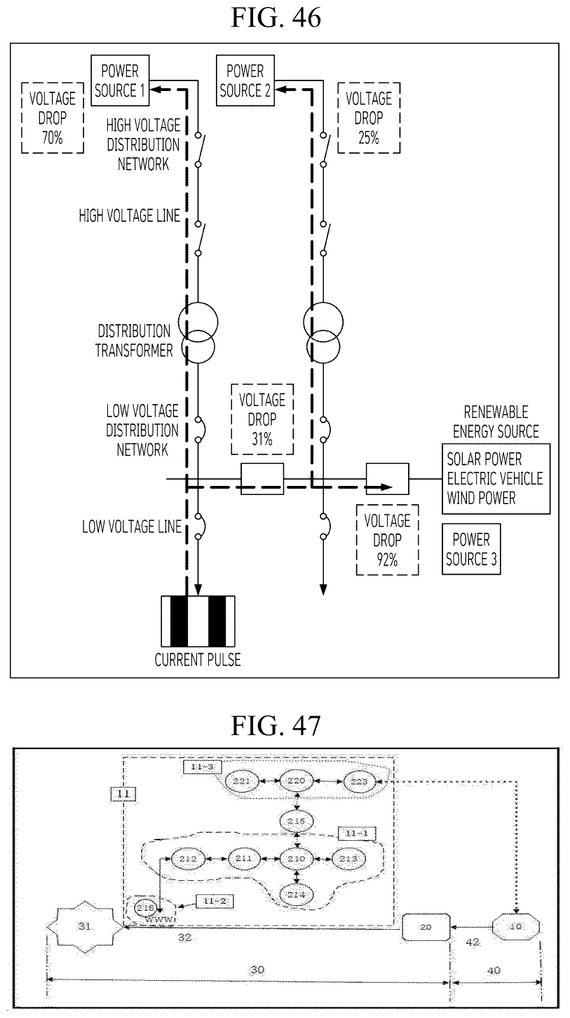

FIG. 46 shows an example of the results of transmitting a current pulse signal as described above, measuring a voltage drop for each section in which the current pulse signal reaches each power source and identifying a route connecting to the power source 2 with the lowest voltage drop.

FIG. 47 shows a receiver structure and a relationship with a transmitter. When, in order to transmit a current pulse signal to a medium voltage section, a transmitter is connected to a specific point of a low voltage line 42 of a low voltage section 40, and a current pulse signal is transmitted, the current pulse signal reaches a transformer 20. When the transformer attenuates the current signal to a ratio of 1/60 to flow to the medium voltage section, and the current signal flows to a medium voltage source 31 through a medium voltage section 30, in receiver 11, a magnetic field sensor 216 of a magnetic field receiving unit 11-2 obtains an induced current through a coil wound on a ferromagnetic part by being inductively coupled to medium voltage line 32 within a near magnetic field distance.

When the magnetic field receiver 11-2 supplies a collected magnetic field signal to a signal detector 212 of a signal detection unit 11-1, a signal processor 211 removes a power frequency and a harmonic signal including a load current included in the magnetic field signal and transmits the magnetic field signal to a main control unit (MCU) 210.

In addition, the signal detection unit 11-1 includes a detection adjuster 213 that may adjust a gain and a TH value for separate signal detection.

MCU 210 transmits collected signal detection-related data to a waveform analysis unit 11-3 through Bluetooth communication 215.

The waveform analysis unit 11-3 reanalyzes received magnetic field signal waveform data and displays results on a waveform analysis and display unit 221 to enable an investigator to visually analyze and identify the waveform characteristics of a received signal.

In addition, receiver 11 has a remote setting function with which it can remotely control a transmitter 10 and may have a basic setting screen for remotely controlling the transmitter using a wireless communication unit 223, thereby generating a current pulse signal.

In remote settings, set values such as settings or changes of a power line to be surveyed, adjustment of a current pulse signal magnitude, a current signal pulse period T, and a duration time t are stored, and the set values are transmitted to the transmitter 10 through wireless communication 223 to initiate current signal generation.

Since receiver 11 has the remote setting function, an surveyor may improve survey efficiency by generating a desired power line phase and various types of current pulse signals without remote assistance or hardware changes of the transmitter.

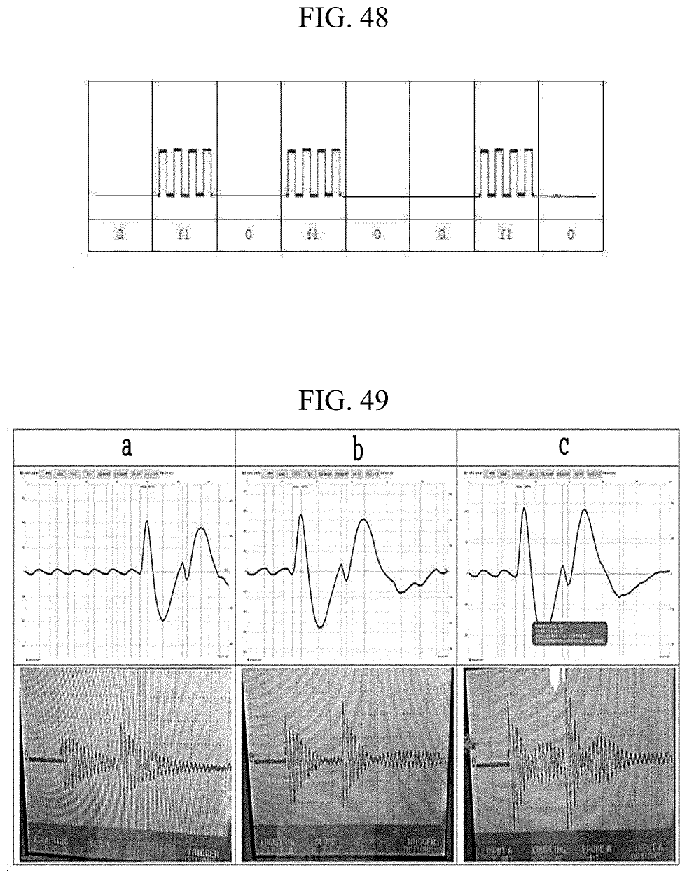

When a current pulse signal as shown in FIG. 48 was transmitted, it was seen that resonance occurred in a magnetic field sensor of FIG. 49. In particular, to increase the sensitivity of magnetic field signal detection, FIG. 49A shows a received waveform when one magnetic field sensor is used, FIG. 49B shows a received waveform when two magnetic field sensors are used, and FIG. 49C shows a waveform when three magnetic field sensors are used. As shown in the drawings, it can be seen that a high frequency signal is received rather than a pulse wave.

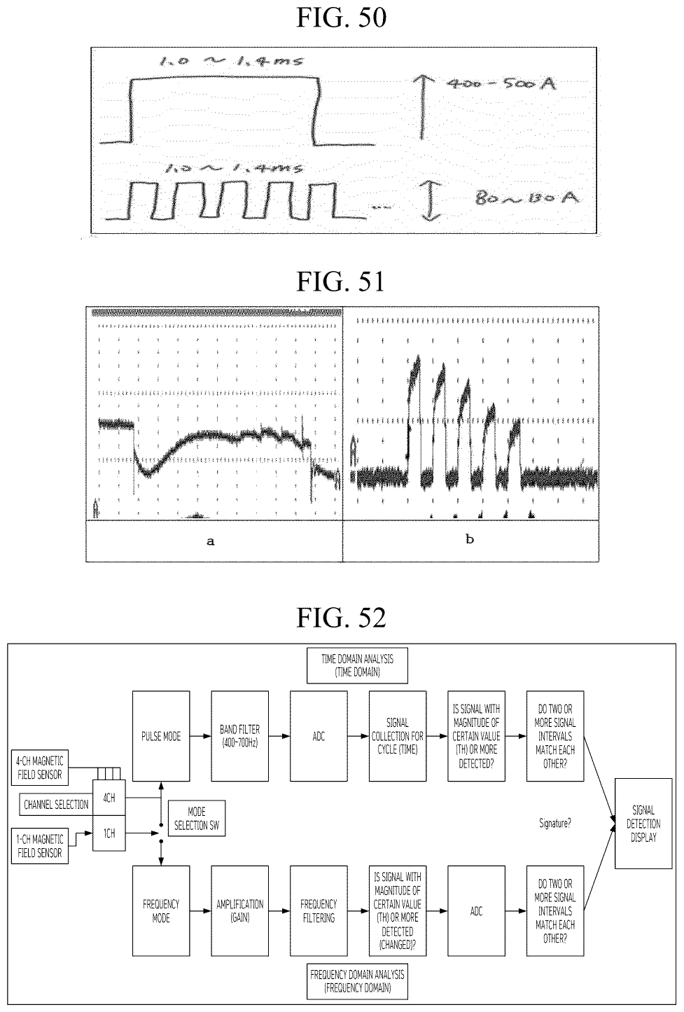

Accordingly, as shown in FIG. 50, the current pulse signals transmission mode can be categorized into two types: pulse mode (time domain) at the top and frequency mode (frequency domain) at the bottom of the table.

In particular, since it was inefficient to continuously transmit a high current pulse signal to a public distribution network, especially when polarity and voltage drop measurements were unnecessary. Additionally, if a signal could not be received because the signal cycle lasted 7 seconds or more due to high current, it created a delay of 14 seconds before the next signal could be sent. To address these issues, the current was reduced to decrease the load on the public distribution network, and the signal transmission interval was shortened to enhance the speed of communication.

FIG. 51 illustrates two different types of waveforms produced by an actual transmitter. In FIG. 51A, a continuous current flows for the entire duration of 1.4 ms. Conversely, FIG. 51B shows that within the same 1.4 ms timeframe, the signal is divided into five segments. This creates a series of current pulse signals (or signatures), each containing a small amount of current.

FIG. 52 illustrates a receiver designed to handle two distinct signal waveform modes: pulse mode and frequency mode. In the present application, the receiver detects signals by being inductively coupled to a medium voltage line, operating within the proximity of a near magnetic field.

A single-channel magnetic field sensor can be used for basic tracking of x and y coordinates. In contrast, a four-channel magnetic field sensor can determine whether the center of a signal corresponds to a left or right signal and can measure the burial depth at a specific location.

In a time domain (pulse) mode, the input power received from a magnetic field sensor is first filtered using a bandpass filter. This filtering process eliminates unwanted power frequency and harmonic signals. The filtered signal is then converted into a digital signal through an analog-to-digital converter (ADC). Finally, the presence or absence of a signal is detected based on a specific cycle.

Then, after comparing an input signal with a threshold value, signatures (signal strings) are assessed. When the signatures match, the signal is confirmed as detected and displayed on a screen.

On the other hand, frequency domain (frequency mode) analysis is performed after three-stage amplification, and then frequency filtering is performed and amplified again to tune the transmission signal frequency. If the signal value passing through the tuning circuit exceeds the threshold, it is converted to digital through the ADC. Then, if it is determined that the signal has been detected after comparing whether the signature matches, the signal value is displayed on the display.

On the other hand, in frequency domain (frequency mode) analysis, after amplification is performed in three stages, the frequency is filtered and then amplified again and is synchronized with a frequency of a transmission signal. When the value of a signal passing through a synchronization circuit exceeds a threshold, the signal is converted into a digital signal through the ADC. Then, when it is determined that a signal is detected after a comparison of whether signatures match each other, a signal value is displayed on a display unit.

In particular, when a signal is transmitted in the frequency mode (domain), the receiver first checks whether the amplified signal's analog value exceeds a certain threshold. This simplifies the signal detection logic and eliminates the need for unnecessary digital conversion. Furthermore, even when a small current is transmitted, it nearly matches the value received from a high-current pulse signal, which enhances transmission efficiency.

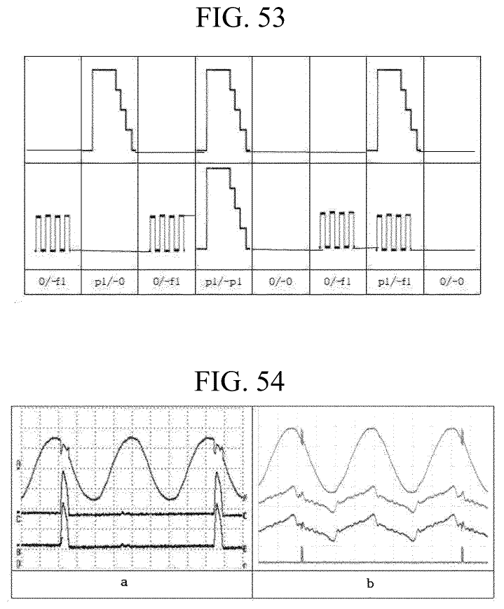

FIG. 53 shows two examples of signal transmission. The upper section shows a scenario where only a time-domain signal is transmitted. In contrast, the lower section depicts a situation where the time-domain signal is combined with a frequency-domain signal during transmission. This approach indicates that, unless it is absolutely necessary, transmission is typically carried out in frequency mode rather than pulse mode in order to reduce output power.

In addition, to reduce average power consumption, when burst signals are transmitted together, the interval between signals is increased. This makes it easier to receive the incoming signal than before.

FIG. 54 compares the signal waveforms and voltage waveforms of pulse mode and frequency mode. In pulse mode, a high current pulse is necessary to initiate a change in the current load magnitude. When the transmitter alters its signal at a specific moment, the receiver detects this change. Therefore, it is essential that the transmitter and receiver are synchronized in both timing and operation.

On the other hand, in frequency mode, the receiver can select, amplify, and filter a specific frequency, making it easier to detect the signal even with low-power transmission. Additionally, when a signal is transmitted based solely on its frequency, independent of time, it can be detected without needing digital conversion.

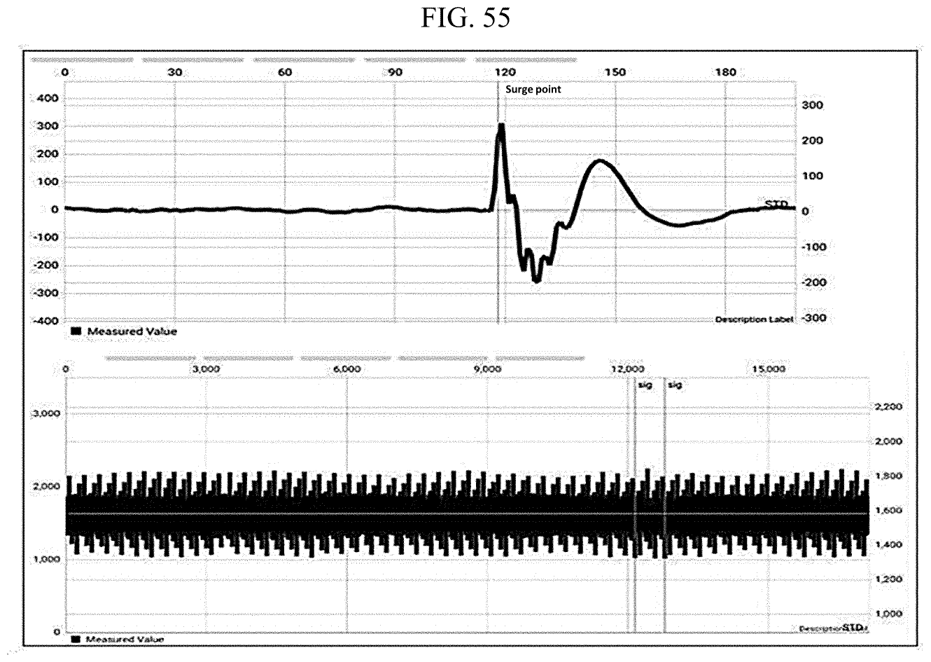

FIG. 55 shows that the signal is received in pulse mode. When the signal repetition period, T, is 7 seconds, as illustrated in FIG. 8, the waveform data gathered during this period is digitally converted and stored in memory, as indicated in the lower part of the drawing.

The information saved in memory is then analyzed to detect changes in levels compared to a threshold. This analysis involves identifying the section of the signal where a change in current is expected, checking for the presence of a predetermined signature, and determining whether there is a match when the signature is present. If a mismatch occurs, the next smaller signal must be examined from the beginning, making the signal processing complex and time-consuming.

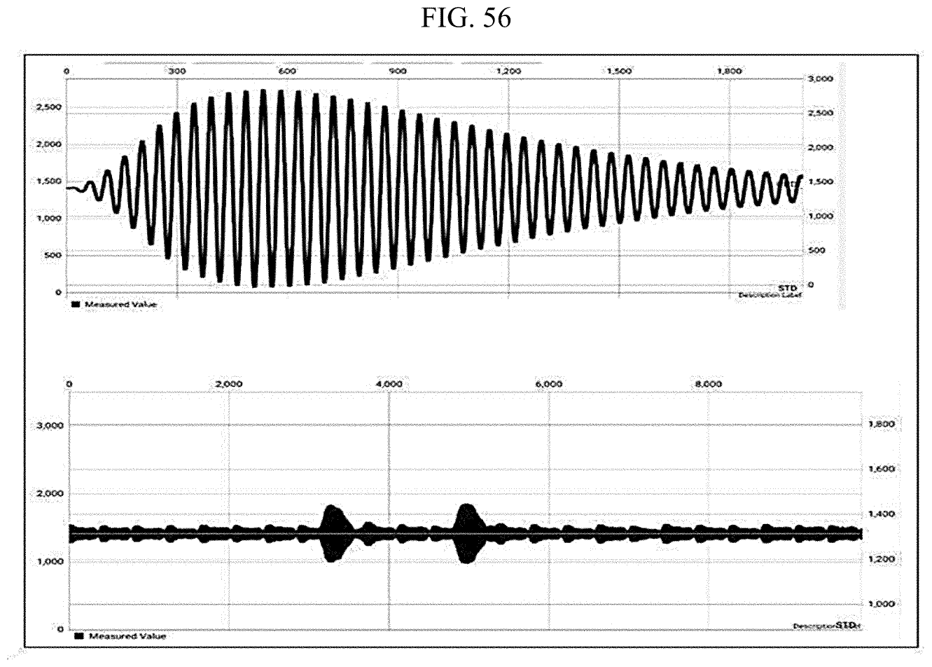

On the other hand, FIG. 56 shows that a frequency domain signal is received. It is not necessary to compare a signal with surrounding signals to find whether there is a change, and it is possible to easily detect a signal by allowing only the signal to pass through a frequency filter. In addition, it is not necessary to store a digitally converted signal in a memory during a signal period T for comparison with the surrounding signals.

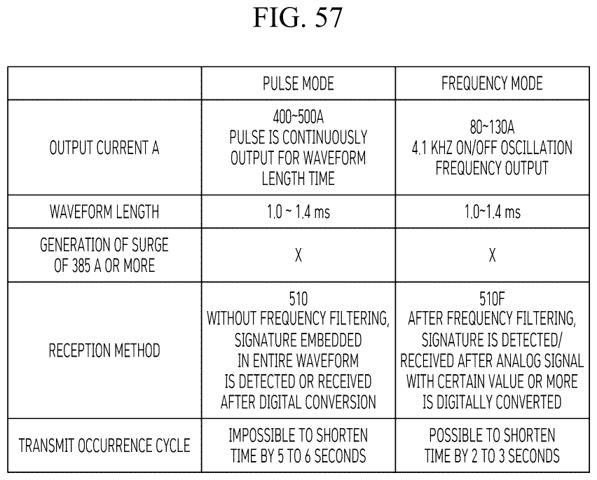

FIG. 57 is a table comparing the characteristics of signal transmission in the time domain (pulse mode) and the frequency domain (frequency mode). As mentioned earlier, in frequency mode, a receiver can maintain the same sensitivity even if the current pulse amplitude is reduced to about one-fourth of that in pulse mode. The comparison table also highlights additional benefits: as the pulse current amplitude decreases, the capacity of the DC-link unit's accumulation means can be reduced to one-tenth or less, and the signal generation cycle can be shortened to just 2 to 3 seconds.

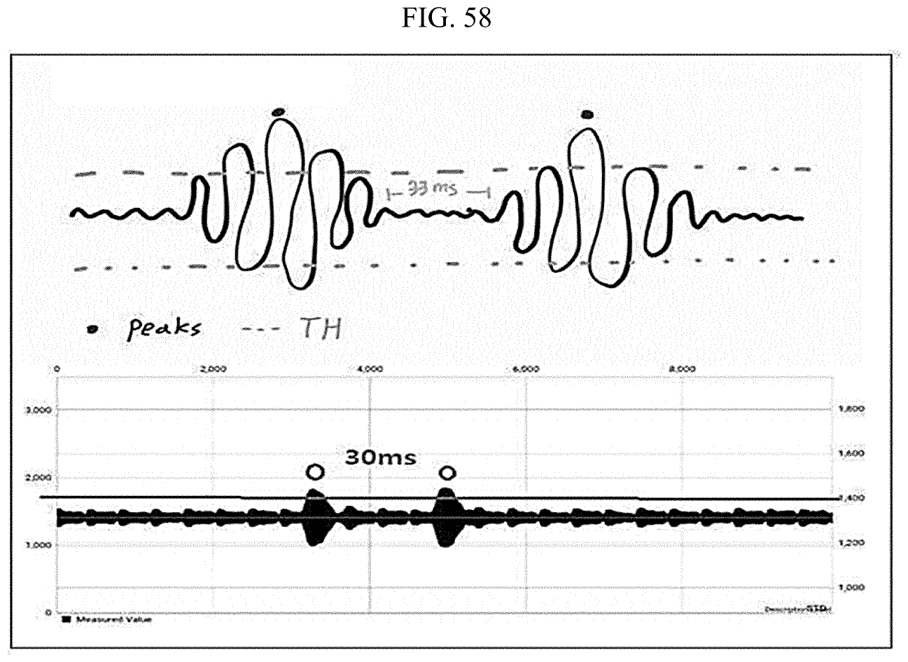

FIG. 58 illustrates the detection of a signature in frequency mode. As shown in FIG. 52, when the receiver is in frequency mode, it processes the input signal through the section labeled “frequency domain” to analyze the frequency mode signal. The receiver amplifies the analog signal by a factor of at least three to increase its amplitude. If the transmitted signal, obtained by frequency-filtering the amplified analog signal, exceeds a certain threshold, it can either be digitally converted or left in its analog form. This process helps determine whether the received analog signal contains significant signature information. The illustration depicts an example of a received signal with a signature value of “0101” at intervals corresponding to a power frequency of 60 Hz.

In this way, the received signal is identified as being valid only if it surpasses a specified threshold after frequency filtering (tuning) has been applied. However, as illustrated in FIG. 55, when a pulse mode signal is received, the magnetic field generated by a current pulse can interact with surrounding noise, which prevents an increase in signal magnitude through constructive interference. In some instances, destructive interference may occur, potentially leading to a decrease in signal strength. This introduces the complexity of needing to digitally convert the received signal during the signal repetition period (time T), store it, and then detect the signal by adjusting the threshold.

On the other hand, in a frequency mode, when a signal-to-noise (SN) ratio is 1:2 or more, signal detection is possible even when destructive interference occurs.

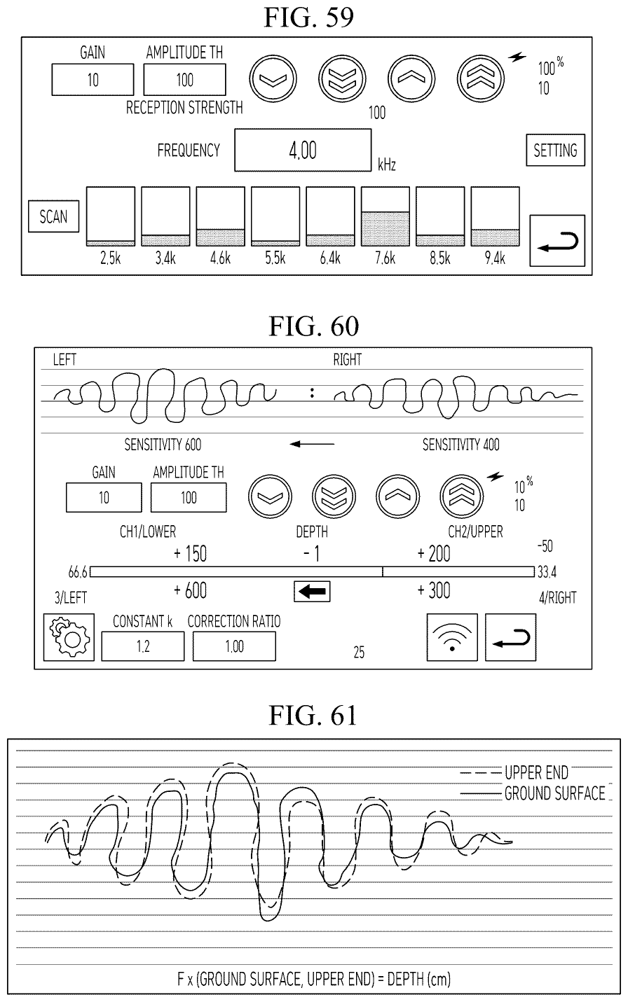

FIG. 59 shows a screen that displays the noise level at a specific reception location. A receiver requires a minimum signal-to-noise (SN) ratio to operate effectively in frequency mode. To ensure optimal performance, the receiver first measures the noise level at its current location before the transmitter sets a frequency. The frequencies with the lowest noise levels displayed on the screen are 2.5 kHz and 5.5 kHz. Consequently, the transmitter sends a current pulse signal at these two frequencies, as illustrated in FIG. 48. The receiver is then inductively coupled to capture the magnetic field signal generated by this transmission.

FIG. 60 describes a method of identifying a lateral intermediate position of a signal using four sensors when a receiver includes two left and right sensors and two upper and lower sensors. The receiver is a sensor in which a coil is wound around a ferromagnetic core and is inductively coupled within a distance of a short wavelength that does not propagate, thereby detecting a magnetic signal generated by a current flow.

A buried object detector, as shown in FIG. 2, typically operates by transmitting signals with a low current of 500 mA or less in a continuous mode rather than a discontinuous mode. As a result, the detector is unable to receive signals from the ground surface when using short-range signal characteristics.

However, in the present application, when a current signal with a magnitude of several tens of amperes and a frequency within the voice frequency band is transmitted over a distance of several meters-typically the distance at which power lines are buried. A receiver, referred to as Receiver 11, is positioned near a medium voltage line on the ground surface. This setup ensures that the magnetic field signal remains intact and travels in a straight line without distortion.

Accordingly, the receiver 11 is equipped with two magnetic field sensors positioned several tens of centimeters apart. It compares the signal magnitudes received by both sensors to determine the center point in the lateral direction.

For example, in the diagram, if the left sensor receives a signal value of 600 and the right sensor receives a value of 400, the receiver indicates movement to the left, where the signal is stronger, as shown by an arrow.

FIG. 61 illustrates the process of depth measurement. As previously mentioned, in short-range scenarios, the effects of transverse influences can be disregarded. Therefore, magnetic field sensors are positioned several tens of centimeters apart vertically, allowing receiver 11 to measure the differences between them.

A sensor positioned closer to the ground surface, termed the lower sensor, receives a stronger signal than a sensor located several tens of centimeters away from the surface, known as the upper sensor.

As shown in FIG. 60, direction can be determined by simply comparing the magnitudes of the signals. However, calculating an unknown depth cannot be achieved solely by comparing the signal strengths between the upper and lower sensors.

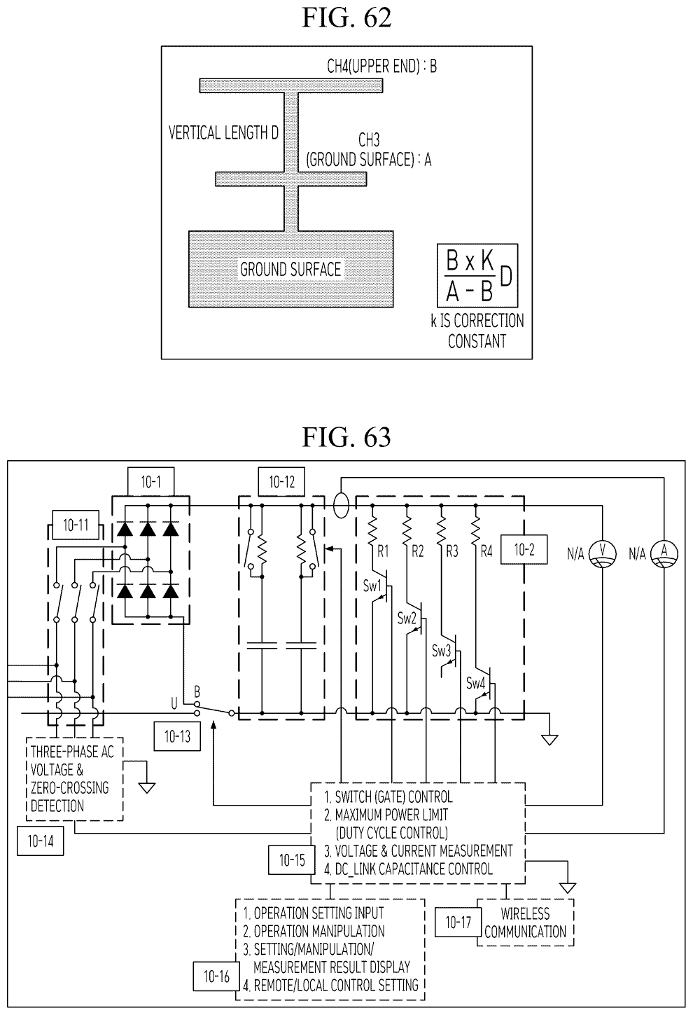

Therefore, to correct the depth measurement, a K correction constant is applied, as illustrated in FIG. 62. Specifically for power lines, manholes are located every 300 meters. Before conducting a survey, the local geological characteristic coefficient, denoted as k, is adjusted. After this correction, the depth is measured. The K correction constant used at the site typically ranges from 2.5 to 4.0; however, these values are not strictly limited to this range and should be considered as reference points.

### Example 2

FIG. 63 illustrates the conceptual circuitry of a transmitter device that generates a current pulse signal using balanced voltage, in contrast to the unbalanced three-phase voltage shown in FIG. 39.

Since the concept of balanced voltage has already been discussed in reference to FIG. 40, a detailed explanation will be omitted here. To give an example, a current pulse is generated using line-to-line voltage, where each voltage in the three-phase input is equal, as there is no neutral line involved.

Of course, a switch (10-13) for connecting a neutral line may be provided to generate unbalanced current pulses when necessary. However, in this description, we will focus more on current pulse signal transmission using balanced voltage.

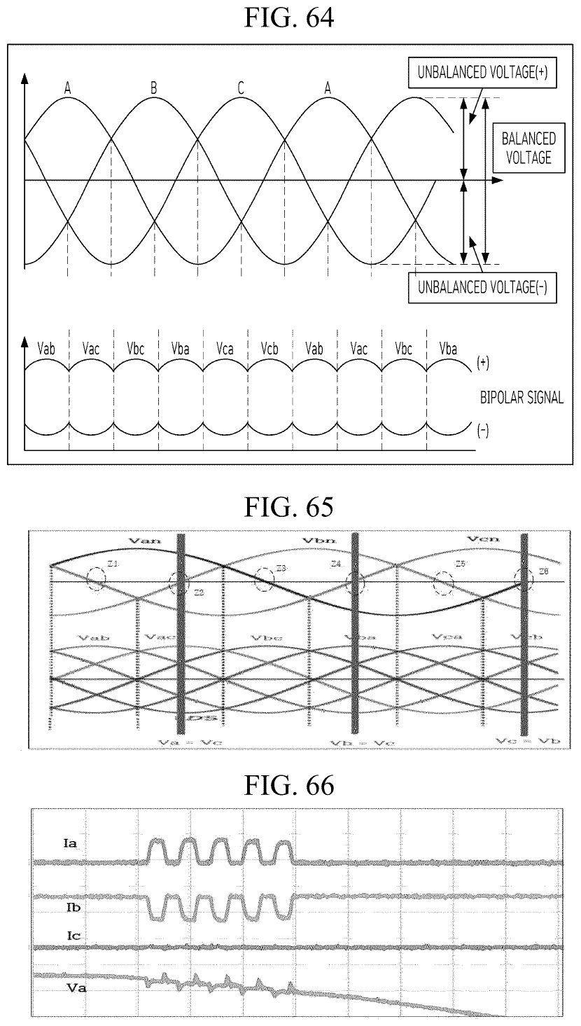

First, referring to FIG. 64, when performing balanced three-phase voltage full-wave rectification over a full cycle (2π), the output consists of line-to-line voltages: Vab, Vac, Vbc, Vba, Vca, and Vcb. These voltages are generated by combining two-phase line voltages and are spaced at intervals of π/3 radians.

In this context, the difference between Vab and Vba shows that the phase represented by the first lowercase letter in the subscript of the three-phase full-wave rectified output voltage is on the positive side. Additionally, the line voltage Vab leads the phase voltage Ea by π/6 radians.

Select two phases to be transmitted from the voltage waveforms combined into those phases (for example, Vab in the case of phases A and B) as shown at the bottom of the drawing. Control the switches (Sw1 to Sw4) according to the phase angle time output, and transmit the current pulse signal to the two selected phases of the public distribution network.

Since a balanced voltage is a line-to-line voltage, its magnitude is root(3) times that of the phase voltage used in Example 1. Consequently, the current decreases to approximately 1/root(3).

In other words, there is an advantage in that when the same amount of power is transmitted, the current is lower compared to Example 1. This means that the same power can be transmitted with less current. However, a disadvantage is that the withstand voltage of the accumulation means must be higher.

In reference to FIG. 63, the system includes the following components: an input unit (10-11) connected to a transformer (10), a three-phase full-wave rectification unit (10-1), a DC-link unit (10-12), an inverter unit (10-2), a balanced/unbalanced voltage selection switch (10-13), a zero-crossing detection unit (10-14), a switch control unit (10-15), an input display unit (10-16), and a wireless communication unit (10-17).

The input unit 10-11 receives a three-phase, three-wire voltage from the low voltage section 40 through a point of connection (POC) and transformer 10. Additionally, the zero-crossing detection unit 10-14 is connected to the input unit 10-11 to measure the voltage and detect the zero-crossing point for each phase. If needed, it can also measure the three-phase current.

The rectification unit 10-1 receives a balanced three-phase voltage from the input unit 10-11 and carries out full-wave rectification. The DC_link unit 10-12 measures the differential value or change in voltage and current input from the rectification unit. It then controls the capacity of the accumulation means by managing the switches (Swc) to ensure that the storage capacity remains adequate, preventing the generation of a surge voltage (V2) in a way that minimizes signal distortion.

Additionally, the cathode voltage of the diode in the rectification unit is controlled during inverter switching to electrically disconnect the transformer and transmitter, preventing resonance from occurring.

The phase angle controllable through switching is limited to 60° when using balanced three-phase voltage for full-wave rectification. To enhance the range of variation in the current signal amplitude, the load resistances (R1 to R4) in the inverter (10-2) are provided in various values. This allows for easy adjustments to the current signal magnitude by selecting different resistance values, in addition to modifying the phase angle.

In Example 2, a combination circuit consisting of R1 and Sw1 was designed to generate a maximum current of 40 A. Similarly, the combination circuit made up of R2 and Sw2 was designed for a maximum current of 60 A, while the circuit with R3 and Sw3 was intended to produce a maximum current of 80 A. Finally, the combination circuit of R4 and Sw4 was designed to deliver a maximum current of 120 A. It is important to note that these current values represent the maximum limits calculated at a voltage with a phase angle of 90°, which corresponds to the highest voltage.

When an output current pulse signal is generated, the current pulse magnitude can reach 40 A when only switch Sw1 is controlled. However, when all switches are controlled, the total current pulse magnitude can reach 300 A, assuming the phase angle is 90°.

A current signal can be transmitted to just one phase, as demonstrated in Example 1, using a balanced three-phase voltage without a rectifier circuit. However, to prevent transient voltage and transformer resonance during switching, it is important to restrict the current flow toward the power source and allow only the current flow toward the load.

The rectification unit features a diode that restricts current flow to a single direction. This design enables the DC_link unit to suppress transient voltage and manage voltage control the cathode in the unit. Furthermore, it helps prevent ferroresonance by isolating the electrical connection between the transformer and the transmitter during the switching process.

In FIG. 65, when a balanced voltage is applied (as shown in FIG. 63), a switch activates at phase angles corresponding to Z1 through Z6. At these angles, one single-phase voltage will be zero while the other two phases will maintain equal voltage, occurring six times per cycle. This setup generates a current pulse that prevents current from flowing through the neutral line, effectively minimizing magnetic field leakage.

FIG. 66 shows that currents in phases a and b are balanced, while no current flows in phase c during switching at the phase angle time Z1 shown in FIG. 65.

Managing the current imbalance can be challenging when switching the output from a balanced three-phase voltage to deliver current pulses in two phases. This issue can be addressed by generating current pulse signals at the phase angles Z1 to Z6, as illustrated in [FIG. 65].

This method allows for the creation of a balanced three-phase current, which helps prevent issues related to residual magnetic flux. In this configuration, equal magnitudes of current flow through the two phases but with opposite polarities, while the voltage in the remaining phase is zero. This results in the cancellation of the magnetic fields from all three phases, ensuring that no external leakage magnetic field is generated.

To reduce the security risks associated with current pulse signal transmission, it is clear that the voltage of phase A (Va), illustrated at the bottom of FIG. 66, remains stable and does not generate excessive voltage. This stability is due to the volt-second balance between the positive and negative polarities.

Since excessive voltage is unlikely to occur, the required capacitance in the DC Link can be achieved using capacitors with values in the range of several microfarads (μF). This approach ensures that the current pulse waveform remains undistorted.

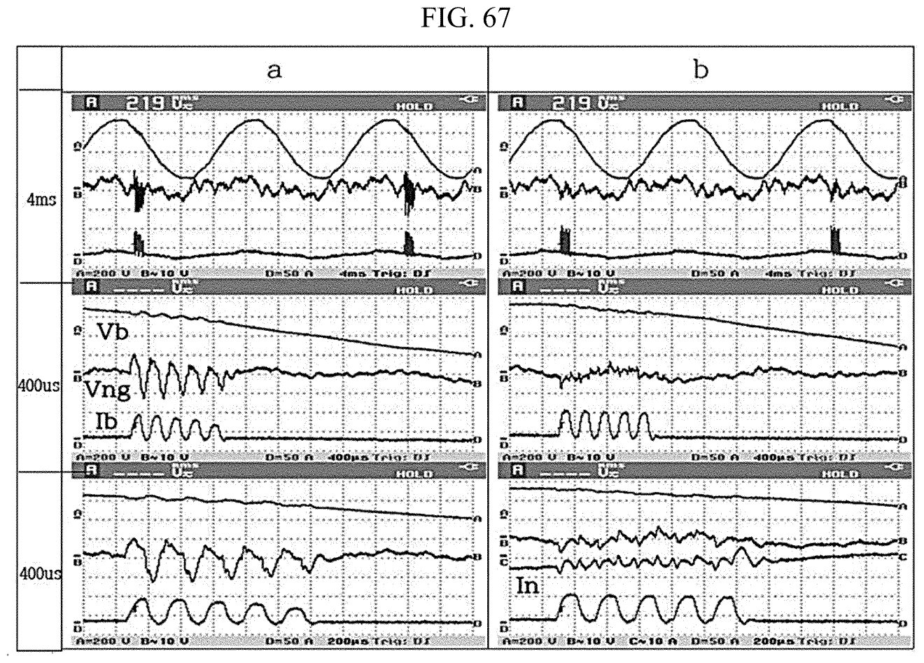

FIG. 67 presents a comparison of waveforms when using unbalanced voltage versus balanced voltage. In FIG. 67A, it is evident that with unbalanced voltage, the current (In) flowing through the neutral line and the current (Ib) flowing through a phase line are equal in value. Additionally, the voltage (Vng) between the neutral line and the ground increases.

On the other hand, in FIG. 67B, it can be observed that when a balanced voltage is applied, there is little to no change in the neutral current, and no voltage rise between the neutral line and the ground is detected. This suggests that using a balanced voltage significantly reduces noise levels compared to the noise produced when a current pulse is generated with an unbalanced voltage.

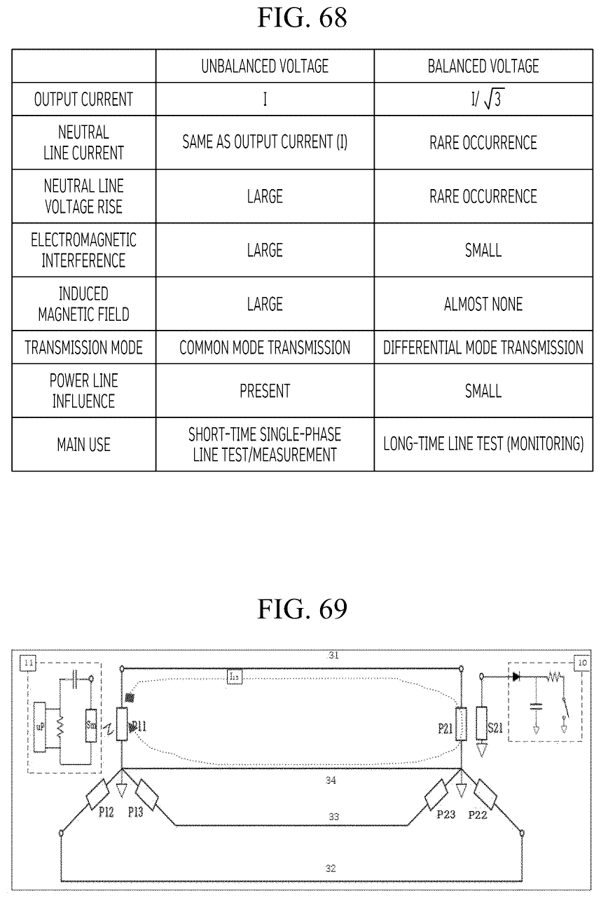

FIG. 68 presents a comparison of characteristics for current pulse signal transmission using unbalanced and balanced voltage in a table. However, by using a neutral line, there is a benefit in that all half-cycles (π) of one phase can be utilized. Therefore, when connecting a large current load, such as an electric vehicle, to a single-phase line as shown in FIG. 46. the unbalanced voltage can be used to measure voltage drop in advance or to explore the path using the characteristics of magnetic imbalance.

In situations where an unbalanced voltage is used to generate a current pulse in frequency mode for surveying, it is possible to minimize ambient noise while producing an unbalanced leakage magnetic field.

As mentioned earlier, by appropriately combining and generating pulse/frequency mode current pulse signals—sometimes using unbalanced or balanced three-phase voltages—it is possible to establish an optimal configuration for surveying a power line.

### Example 3

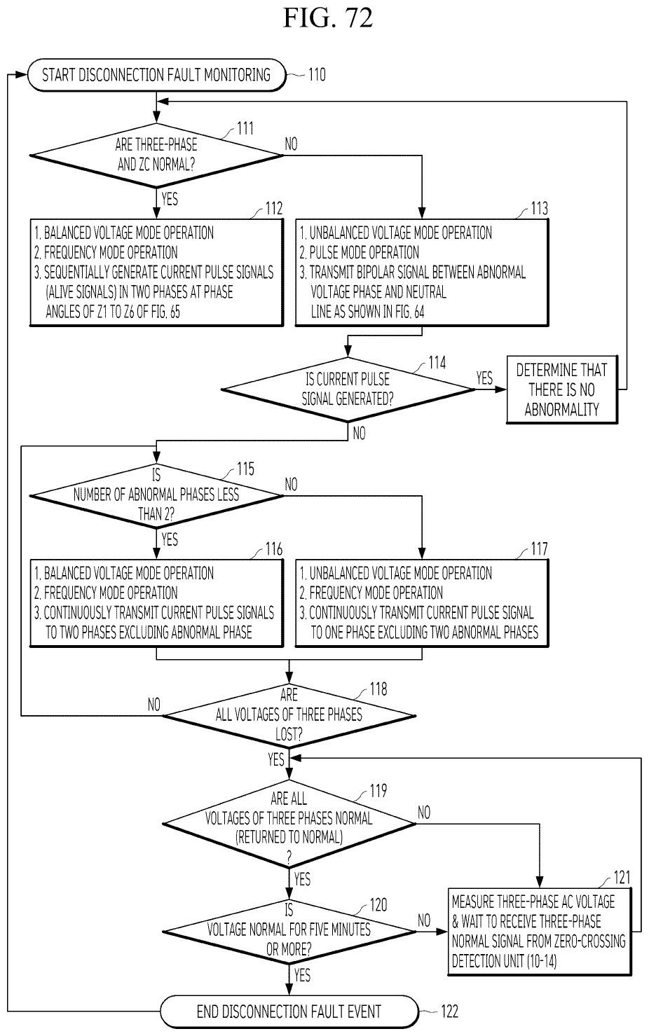

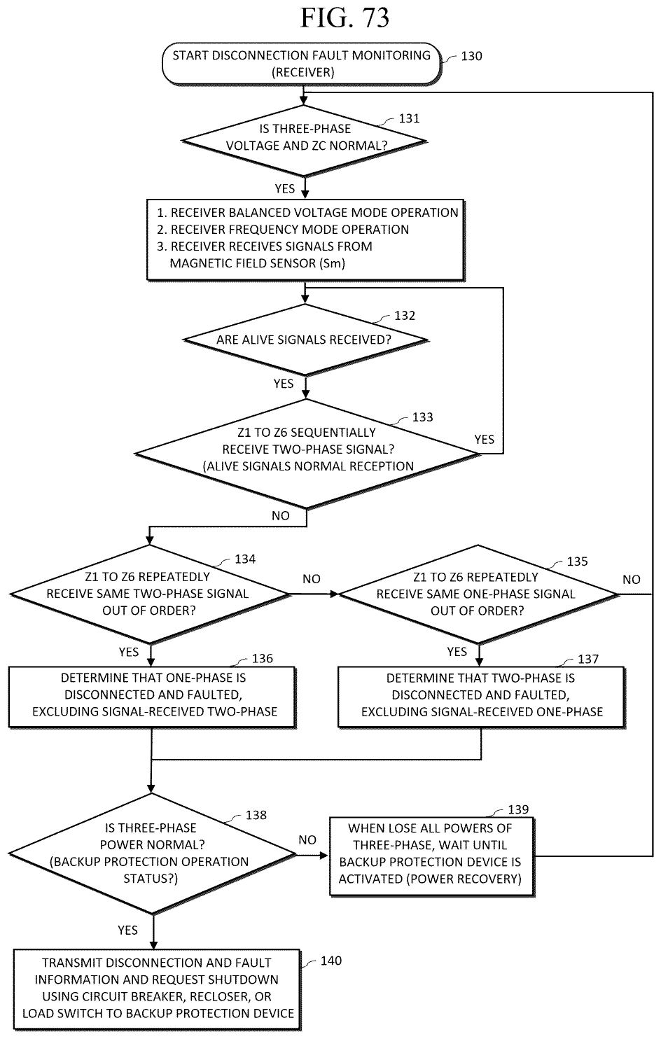

FIGS. 69 to 73 illustrate a configuration for detecting ground faults on power lines using current pulse signal transmission technology, as described in Example 3. For clarity and ease of understanding, the explanation focuses on a single-phase or two-phase circuit rather than a three-phase circuit.

In FIG. 69, a transmitter (10) is connected to a low-voltage single-phase winding (S21) of a transformer, which experiences an unbalanced voltage. The transmitter sends a current pulse signal through the primary winding (P21) of the transformer to the medium-voltage winding P11 of the opposite transformer via the medium-voltage power line (31).

Meanwhile, the receiver captures the current pulse signal by positioning a magnetic field sensor within the near-field distance. This occurs as the current pulse signal flows through both the medium-voltage power line (31) and the medium-voltage winding P11.

When using the unbalanced voltage mentioned earlier, the medium-voltage current is supplied from transformer P11 to the primary winding P21 of the load-side transformer via the medium-voltage power line 31. This current is then converted to low voltage through the low-voltage winding (S21) and delivered to the transmitter (10). Finally, it returns to the other terminal of the P11 winding through the neutral line (34).

The transmitter (10) on the load side continuously measures the three-phase voltage and the zero crossing time for each phase using the three-phase voltage measurement and zero crossing detection unit (10-14) under normal conditions (111).

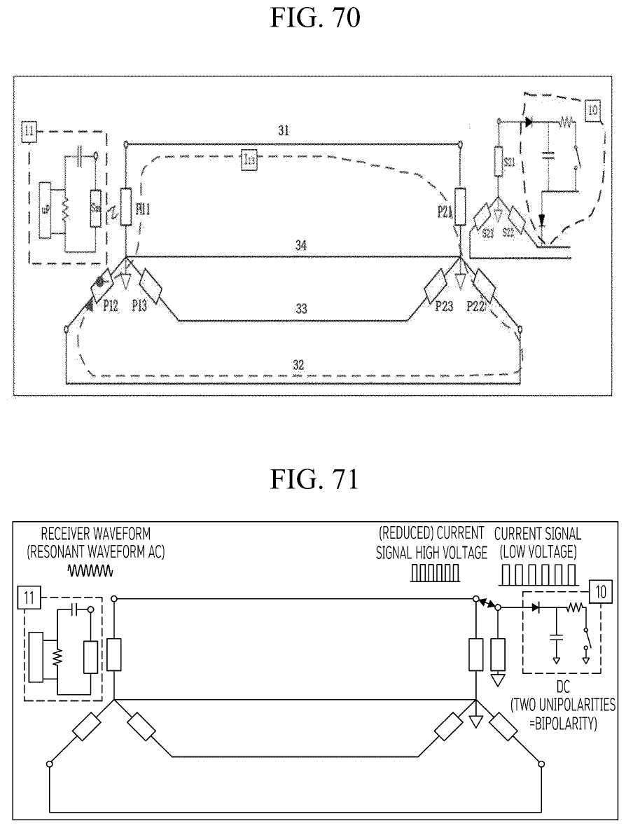

If the three-phase voltage and the zero-crossing times for each phase are healthy, as shown in FIG. 70, the balanced voltage across two phases (S21-S22) can be used to generate a current pulse signal with the transmitter. This signal is then transmitted to the primary windings P11 and P12 of the power transformer, traveling through the medium voltage power lines 31 and 32 via the transformer's primary windings (P21-P22).

As shown in FIG. 69, the receiver measures and receives a magnetic field signal within a near magnetic field distance around a corresponding winding or power line.

If the transmitter (10) determines that the three-phase voltage is normal, it sends a current pulse signal to the power-side transformer at specific phase angles, ranging from Z1 to Z6, as illustrated in [FIG. 65]. This occurs in balanced voltage and frequency mode (112). In this mode, a two-phase output is utilized at every π/3 interval.

Additionally, the transmitter transmits an Alive signal sequentially during the period from Z1 to Z6, which corresponds to the three-phase balanced current. This allows the power-side receiver to verify that the transmitter is operating normally, and the receiver can confirm that it is functioning properly as well (133).

Then, if the transmitter suspects that the three-phase voltage is abnormal, it first generates a current pulse signal in the unbalanced pulse mode for the corresponding phase, and if the current pulse waveform is not generated, it confirms the previous suspicion as abnormal. (115)

When an abnormality is confirmed, this determination is sent to the power source receiver to provide a notification, allowing the receiver to disconnect the power supply. If it is determined that one phase is disconnected and faulty, a current pulse signal is continuously generated in the other two phases. This occurs in a different sequence from the normal transmission order of Z1 to Z6 (116).

When two phases are determined to be disconnected and faulted, a current pulse signal is continuously transmitted to the remaining phase in an unbalanced voltage and frequency mode, as shown in (116) and (117).

After notifying the receiver of the occurrence of a disconnection (ground) fault as above, if the receiver cooperates with the backup protection device to trip the power supply, then the transmitter confirms the loss of 3-phase power.

In addition, at this time, wireless communication (10-17) means can be used to send a message to the receiver (notation omitted) indicating a successful power cut due to a disconnection fault.

If the power is restored later after the power outage, the maintenance time is measured, for example, if the three-phase power is normal (121) for more than 5 minutes without any problems, the transmitter transmits an ALive signal to the receiver to notify that the power has been restored (112).

When the receiver is notified of a disconnection failure from the transmitter, it notifies the backup protection device so that it can trip the power supply (140).

If the backup protection device was activated before that and the power to the receiver was lost, it waits until the backup protection device is re-closed and then re-judges.

As described above, in Example 3, unlike conventional technology, a current pulse signal is transmitted to an actual phase line in a burst mode without the use of a neutral line, and the receiver may receive the current pulse signal to immediately know which phase has a disconnection fault.

Through such a configuration,
(1) Regardless of whether the faulty line generates a fault current, the transmitter located on the load side continuously monitors for any voltage abnormalities. If an abnormal voltage is detected, a current pulse is generated for the corresponding phase to determine if the issue is due to ghost voltage. If no current pulse is generated, it is concluded that a disconnection fault has occurred.
(2) Since the current pulse signal exhibits frequency characteristics, it is possible to transmit signals for each phase regardless of the load current, provided that the signal-to-noise ratio is ½ or higher. Additionally, the receiver can identify noise characteristics by frequency in advance. To ensure the transmission of disconnection fault information, it is essential to detect medium-voltage line disconnection faults regardless of whether a fault current occurs. This detection should be effective in both underground and overhead distribution installations, irrespective of low-voltage line multi-grounding.

When the transmitter (10) is connected and there is no abnormality, the current pulse signal is continuously sent to the receiver periodically in the order (Vab->Vac->Vbc . . . Vcb) as shown in the lower part of FIG. 64 using the balanced voltage at a cycle of 2 to 3 seconds to notify that the two phases are operating normally (alive signal).

The alive signal is periodically transmitted to the source-side receiver using a balanced voltage, which offers several benefits:
1. No External Leakage Magnetic Field: The balanced magnetic field prevents the generation of external leakage, eliminating any radio noise.
2. Absence of Residual Magnetic Flux: The balanced positive and negative polarity prevents the buildup of residual magnetic flux in the transformer (transmitter side). As a result, there is no surge voltage produced.
3. Operational Reliability: By periodically sending an alive signal to the receivers (receiving party), the system can confirm normal operation, thereby enhancing overall reliability.

When a zero-crossing detection unit 10-14 detects a loss of a phase voltage, a current pulse signal is generated using an unbalanced voltage of phase A, in which it is determined that there is a loss of a voltage of phase A, to verify once again that the loss of the voltage of phase A is not due to a ghost voltage.

If the current pulse signal for phase A is generated using an unbalanced voltage but does not occur, this indicates a disconnection fault confirmed.

If the current pulse continues to be generated more than twice using the balanced voltage from the two remaining (healthy) phases (B and C), in an order different from what is shown at the bottom of FIG. 64, the receiver will detect that a fault has occurred upon receiving these differently ordered current signals.

When the receiver recognizes such a fact, an ACK signal may be transmitted through a wireless communication unit 10-17.

When the transmitter detects a loss of a voltage of two phases, an unbalanced voltage of the remaining one phase is used to notify the receiver of whether there is an abnormality.

FIG. 70 illustrates a signal generated by each transmitter, a signal attenuated through a transformer, and a signal waveform received by a receiver.

A method of notifying of a fault line according to Example 3 includes starting disconnection fault monitoring, determining whether a three-phase voltage and zero-crossing (zc) are normal, performing an operation in a balanced voltage mode and a frequency mode when the three-phase voltage and the zc are normal, performing an operation in an unbalanced voltage mode and a pulse mode when the three-phase voltage and the zc are abnormal, determining whether a current pulse signal is generated during the operation in the unbalanced voltage mode and determining that disconnection does not occur when the current pulse signal is generated, determining whether a current pulse signal is generated during the operation in the unbalanced voltage mode and determining whether the current pulse signal is less than a predetermined value of an abnormal voltage phase when the current pulse signal is not generated, when the predetermined value is satisfied, performing the operation in the balanced voltage mode and the frequency mode and continuously transmitting a frequency current signal to two phases excluding the abnormal voltage phase, when the predetermined value is not satisfied, performing the operation in the unbalanced voltage mode and the pulse mode and continuously transmitting a frequency current signal to one phase excluding two abnormal voltage phases, and determining whether all three-phase voltages have been restored to normal for a predetermined time and determining that a disconnection fault event has ended.

What is claimed is:

1. A method of surveying a power line by changing a pulse/frequency mode using a balanced/unbalanced three-phase voltage source and transmitting a current pulse signal to a public distribution network.

2. A device for surveying a power line by changing a pulse/frequency mode using a balanced/unbalanced three-phase voltage source and transmitting a current pulse signal to a public distribution network.

3. A device for surveying a power line by changing a pulse/frequency mode using a balanced/unbalanced three-phase voltage source and transmitting a current pulse signal to a public distribution network,
the device comprising a transmitter and a receiver,
wherein the transmitter includes:
a connection unit configured to receive a single-phase AC voltage at a point of connection (POC) which is a point of the public distribution network;
a converter unit configured to convert an input AC voltage into a DC voltage (V+);
an inverter unit configured to switch a DC voltage (V+) of a converter at a set phase angle time and transmit a current pulse signal to a power source of the public distribution network through a pure resistive load (LR); and
a DC_link unit provided between the inverter unit and the converter unit and configured to suppress a transient voltage.

4. The device of claim 3, wherein the DC_link unit includes an accumulator.

5. The device of claim 4, wherein a POC of the connection unit, the converter, and the accumulator are connected to one terminal of a secondary winding of a transformer to constitute a first closed circuit.

6. The device of claim 5, wherein the inverter unit includes a load resistor and a switch connected to the load resistor in series, and
in parallel with one terminal of the accumulator of the first closed circuit, the load resistor of the inverter unit and the switch connected to the load resistor in series are connected to the other terminal of the accumulator of the first closed circuit in series to constitute a second closed circuit.

7. The device of claim 6, wherein charged charging capacity of the accumulator is charged with a maximum voltage, and the second closed circuit is controlled to maintain an OFF state until a gate control signal of the switch arrives and electrically separate the secondary winding of the transformer from the transmitter to prevent ferroresonance.

8. The device of claim 3, wherein the transmitter receives unbalanced three-phase input power to perform a full-wave rectification, selects one phase of three phases through a program, and outputs a dipolar current pulse signal to the one phase and a neutral line at a half-cycle interval.

9. The device of claim 7, wherein the transmitter transmits a high current pulse signal having polarity at a cycle interval.

10. The device of claim 7, wherein the device for surveying a power line is controlled such that, when a switch (SW) is turned on (P1), after a time at which the accumulator supplies a charging current to a load, a cathode voltage of a diode (D) is lowered, changed, and forward biased to electrically connect the transformer and the transmitter.

11. The device of claim 3, wherein the receiver includes:
a magnetic field receiving unit inductively coupled to a high voltage line within a near magnetic field distance to obtain an induced current through a coil wound on a ferromagnetic part;
a signal detection unit including a signal detector configured to receive a collected magnetic field signal, a signal processor configured to remove a power frequency and a harmonic signal including a load current included in the magnetic field signal, a detection adjuster configured to adjust a gain and a TH value for separate signal detection, and a main control unit (MCU) configured to transmit collected signal detection-related data; and
a waveform analysis unit configured to receive the detection-related data from the MCU, reanalyze magnetic field signal waveform data, and display a result thereof.

12. The device of claim 11, wherein the magnetic field sensor is configured to receive a pulse mode or a frequency mode.

13. The device of claim 12, wherein the magnetic field sensor includes a 1-channel magnetic field sensor configured to track x,y coordinates and a 4-channel magnetic field sensor configured to identify a center of a signal.

14. The device of claim 13, wherein, in the reception of the pulse mode, input power received from the magnetic field sensor is filtered using a bandpass filter to remove an unnecessary power frequency and a harmonic signal and then digitally converted through an analog-to-digital converter (ADC) to then detect whether a signal is present according to a cycle, and the magnetic field sensor is controlled such that, after an input signal is compared with a threshold, signatures (signal strings) are compared, and when the signatures match each other, it is determined that a signal has been detected.

15. The device of claim 13, wherein, in the reception of the frequency mode, control is performed such that, after amplification is performed in three stages, a frequency is filtered, amplified again, and then synchronized with a transmitted signal, when a value of a signal passing through a synchronization circuit exceeds a threshold, the signal is digitally converted through an analog-to-digital converter (ADC), and after whether signatures match each other is determined, when it is determined that a signal has been detected, a value of the signal is displayed on a display unit.

16. A method of notifying of a disconnection fault line, the method comprising:
starting disconnection fault monitoring;
determining whether a three-phase voltage and zero-crossing (zc) are normal;
performing an operation in a balanced voltage mode and a frequency mode when the three-phase voltage and the zc are normal, and performing an operation in an unbalanced voltage mode and a pulse mode when the three-phase voltage and the zc are abnormal;
determining whether a current pulse signal is generated during the operation in the unbalanced voltage mode and determining that disconnection has not occurred when the current pulse signal is generated;
determining whether a current pulse signal is generated during the operation in the unbalanced voltage mode and determining whether a value is less than a predetermined value of an abnormal voltage phase when the current pulse signal is not generated;
when the value is less than the predetermined value, performing the operation in the balanced voltage mode and the frequency mode and continuously transmitting a frequency current signal to two phases excluding the abnormal voltage phase;
when the value is not less than the predetermined value, performing the operation in the unbalanced voltage mode and the pulse mode and continuously transmitting a frequency current signal to one phase excluding two abnormal voltage phases; and
determining whether all three phase voltages have been restored to normal for a predetermined time and determining that a disconnection fault event has ended.
